(19) United States
(12) Patent Application Publication
(10) Pub. No.: US 2026/0170197 A1
(43) Pub. Date: Jun. 18, 2026

(54) GRAPH-MODELING-BASED LCS MONITORING SYSTEM

(71) Applicant: Dell Products L.P., Round Rock, TX (US)

(72) Inventors: Douglas Lang Farley, Round Rock, TX (US); Deepak Gaikwad, Natick, MA (US); Rohan Surana, Fremont, CA (US)

(21) Appl. No.: 18/983,833

(22) Filed: Dec. 17, 2024

(51) Int. Cl. G06F 30/20

(52) U.S. Cl. CPC G06F 30/20

(57) ABSTRACT

A graph-modeling-based LCS monitoring system includes a resource management system coupled to resource devices. The resource management system identifies the resource devices and generates an LCS monitoring graph model with resource device nodes identifying the resource devices, and respective resource operation nodes connected via edges to those resource device nodes and configured to identify a current operation of their identified resource devices. The resource management system then composes an LCS using a first subset of the resource devices and, in response, updates the LCS monitoring graph model to include an LCS node that identifies the LCS and that is connected to the resource device nodes identifying the first subset of the resource devices. The resource management system then uses information identified from respective resource operation node(s) connected to the resource device nodes identifying the first subset of the resource devices to perform LCS monitoring operation(s) for the LCS.

### BACKGROUND

The present disclosure relates generally to information handling systems, and more particularly to the use of graph modeling to monitor Logically Composed Systems (LCSs) that are provided by information handling systems.

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

While conventional information handling systems such as, for example, server devices and/or other computing devices known in the art have traditionally been provided with particular information handling systems components that configure it to satisfy one or more use cases, new computing paradigms provide for the allocation of resources from information handling systems and/or information handling system components for use in Logically Composed Systems (LCSs) that may be composed as needed to satisfy any computing intent/workload, and then decomposed such that those resources may be utilized in other LCSs. As such, users of the LCSs may be provided with LCSs that meet their current needs for any particular workload they require.

For example, an LCS may be provided using Bare Metal Servers (BMSs), with processing resources and memory resources in the BMS used to provide an Operating System (OS) for the LCS, and with different resources that may be included in the BMS and/or that are connected to the BMS via a network used to provide any desired functionality for the LCS. As such, LCSs may be composed of disaggregated, heterogeneous resources such as firmware, hardware, microvisors, that may be used to perform operations for that LCS, or for “nested” LCSs that may be provided using that LCS. The inventors of the present disclosure have recognized that the relatively low-level, real-time monitoring of such LCSs would be beneficial in understanding and reporting the operations of the resources providing the LCS, enabling the billing of the utilization of any particular resources, forecasting the future use of resources for LCSs, remediation of configuration “drifts” by resources that provide LCSs, and/or providing other monitoring benefits that would be apparent to one of skill in the art in possession of the present disclosure. While conventional virtual machine provisioning systems provide some limited abilities to track virtual machine utilization, those techniques simply do not allow for granular and accurate tracking of each of the components used to provide the LCS, or the utilization of the “nested” LCSs discussed above, particularly when infrastructure layers “beneath” the operating system for the LCS (e.g., firmware and/or hardware) change due to updates, availability, and/or for other reasons.

Accordingly, it would be desirable to provide an LCS monitoring system that addresses the issues discussed above.

### SUMMARY

According to one embodiment, an Information Handling System (IHS) includes a processing system; and a memory system that is coupled to the processing system and that includes instructions that, when executed by the processing system, cause the processing system to provide a resource management engine that is configured to: identify a plurality of resource devices that are coupled to the processing system and, in response, generate a Logically Composed System (LCS) monitoring graph model that includes: respective resource device graph model nodes identifying each of the plurality of resource devices; and a respective resource operation graph model node connected to each of the respective resource device graph model nodes via a respective graph model edge, wherein each respective resource operation graph model node is configured to identify a current operation of the resource device identified by the respective resource device graph model node connected to that respective resource information graph model node; compose an LCS using a first subset of the plurality of resource devices and, in response, update the LCS monitoring graph model to include: an LCS graph model node that identifies the LCS and that is connected to the respective resource device graph model nodes identifying each of first subset of the plurality of resource devices used to compose the LCS; and perform, using information identified from at least one of the respective resource operation graph model nodes connected to the respective resource device graph model nodes that identify each of first subset of the plurality of resource devices used to compose the LCS, at least one LCS monitoring operation for the LCS.

### BRIEF DESCRIPTION OF THE DRAWINGS

FIG. 1 is a schematic view illustrating an embodiment of an Information Handling System (IHS).

FIG. 2 is a schematic view illustrating an embodiment of an LCS provisioning system.

FIG. 3 is a schematic view illustrating an embodiment of an LCS provisioning subsystem that may be included in the LCS provisioning system of FIG. 2.

FIG. 4 is a schematic view illustrating an embodiment of a resource system that may be included in the LCS provisioning subsystem of FIG. 3.

FIG. 5 is a schematic view illustrating an embodiment of the provisioning of an LCS using the LCS provisioning system of FIG. 2.

FIG. 6 is a schematic view illustrating an embodiment of the provisioning of an LCS using the LCS provisioning system of FIG. 2.

FIG. 7 is a flow chart illustrating an embodiment of a method for monitoring an LCS using graph modeling.

FIG. 8 is a schematic view illustrating an embodiment of a resource management system in the LCS provisioning subsystem of FIG. 3 operating during the method of FIG. 7.

FIG. 9A is a schematic view illustrating an embodiment of the resource management system of FIG. 8 operating during the method of FIG. 7.

FIG. 9B is a schematic view illustrating an embodiment of the resource management system of FIG. 8 operating during the method of FIG. 7.

FIG. 10A is a schematic view illustrating an embodiment of a resource management system in the LCS provisioning subsystem of FIG. 3 operating during the method of FIG. 7.

FIG. 10B is a schematic view illustrating an embodiment of the resource management system of FIG. 10A operating during the method of FIG. 7.

FIG. 11 is a schematic view illustrating an embodiment of the resource management system of FIG. 10A operating during the method of FIG. 7.

FIG. 12A is a schematic view illustrating an embodiment of a resource management system in the LCS provisioning subsystem of FIG. 3 operating during the method of FIG. 7.

FIG. 12B is a schematic view illustrating an embodiment of the resource management system of FIG. 12A operating during the method of FIG. 7.

FIG. 13 is a schematic view illustrating an embodiment of the resource management system of FIG. 12A operating during the method of FIG. 7.

FIG. 14A is a schematic view illustrating an embodiment of a resource management system in the LCS provisioning subsystem of FIG. 3 operating during the method of FIG. 7.

FIG. 14B is a schematic view illustrating an embodiment of the resource management system of FIG. 14A operating during the method of FIG. 7.

FIG. 15 is a schematic view illustrating an embodiment of the resource management system of FIG. 14A operating during the method of FIG. 7.

FIG. 16A is a schematic view illustrating an embodiment of a resource management system in the LCS provisioning subsystem of FIG. 3 operating during the method of FIG. 7.

FIG. 16B is a schematic view illustrating an embodiment of the resource management system of FIG. 16A operating during the method of FIG. 7.

FIG. 16C is a schematic view illustrating an embodiment of the resource management system of FIG. 16A operating during the method of FIG. 7.

FIG. 16D is a schematic view illustrating an embodiment of the resource management system of FIG. 16A operating during the method of FIG. 7.

### DETAILED DESCRIPTION

For purposes of this disclosure, an information handling system may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (e.g., desktop or laptop), tablet computer, mobile device (e.g., personal digital assistant (PDA) or smart phone), server (e.g., blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

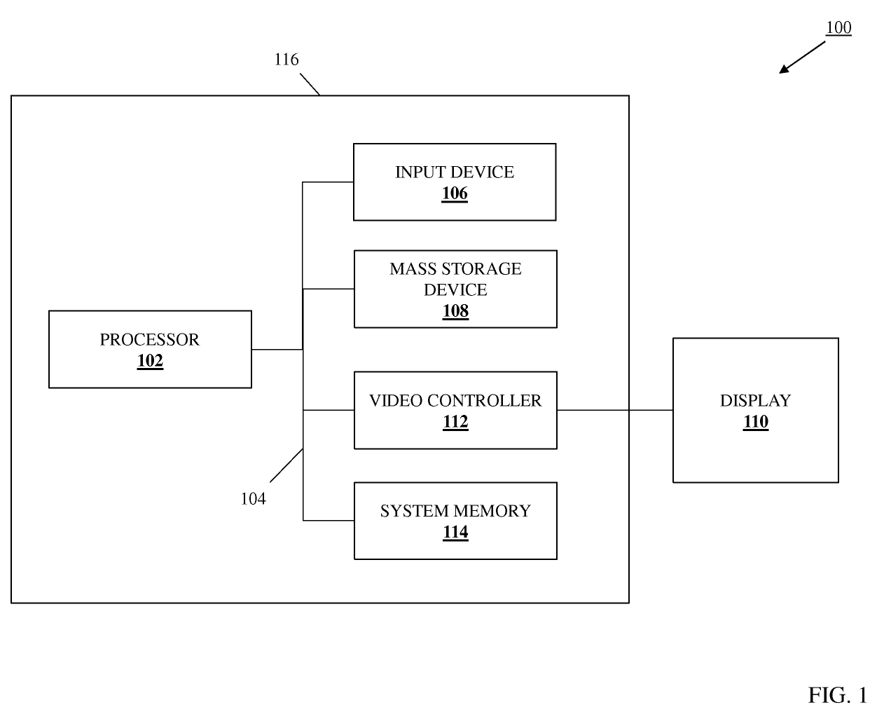

In one embodiment, IHS 100, FIG. 1, includes a processor 102, which is connected to a bus 104. Bus 104 serves as a connection between processor 102 and other components of IHS 100. An input device 106 is coupled to processor 102 to provide input to processor 102. Examples of input devices may include keyboards, touchscreens, pointing devices such as mouses, trackballs, and trackpads, and/or a variety of other input devices known in the art. Programs and data are stored on a mass storage device 108, which is coupled to processor 102. Examples of mass storage devices may include hard discs, optical disks, magneto-optical discs, solid-state storage devices, and/or a variety of other mass storage devices known in the art. IHS 100 further includes a display 110, which is coupled to processor 102 by a video controller 112. A system memory 114 is coupled to processor 102 to provide the processor with fast storage to facilitate execution of computer programs by processor 102. Examples of system memory may include random access memory (RAM) devices such as dynamic RAM (DRAM), synchronous DRAM (SDRAM), solid state memory devices, and/or a variety of other memory devices known in the art. In an embodiment, a chassis 116 houses some or all of the components of IHS 100. It should be understood that other buses and intermediate circuits can be deployed between the components described above and processor 102 to facilitate interconnection between the components and the processor 102.

As discussed in further detail below, the graph-modeling-based LCS monitoring systems and methods of the present disclosure may be utilized with Logically Composed Systems (LCSs), which one of skill in the art in possession of the present disclosure will recognize may be provided to users as part of an intent-based, as-a-Service delivery platform that enables multi-cloud computing while keeping the corresponding infrastructure that is utilized to do so “invisible” to the user in order to, for example, simplify the user/workload performance experience. As such, the LCSs discussed herein enable relatively rapid utilization of technology from a relatively broader resource pool, optimize the allocation of resources to workloads to provide improved scalability and efficiency, enable seamless introduction of new technologies and value-add services, and/or provide a variety of other benefits that would be apparent to one of skill in the art in possession of the present disclosure.

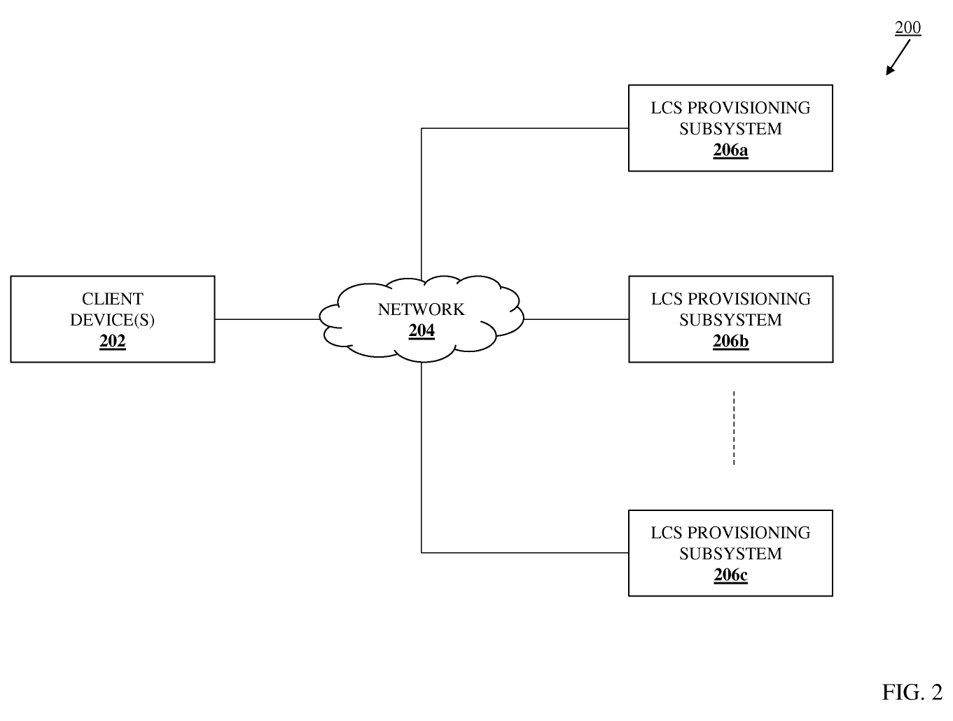

With reference to FIG. 2, an embodiment of a Logically Composed System (LCS) provisioning system 200 is illustrated that may be utilized with the graph-modeling-based LCS monitoring systems and methods of the present disclosure. In the illustrated embodiment, the LCS provisioning system 200 includes one or more client devices 202. In an embodiment, any or all of the client devices may be provided by the IHS 100 discussed above with reference to FIG. 1 and/or may include some or all of the components of the IHS 100, and in specific examples may be provided by desktop computing devices, laptop/notebook computing devices, tablet computing devices, mobile phones, and/or any other computing device known in the art. However, while illustrated and discussed as being provided by specific computing devices, one of skill in the art in possession of the present disclosure will recognize that the functionality of the client device(s) 202 discussed below may be provided by other computing devices that are configured to operate similarly as the client device(s) 202 discussed below, and that one of skill in the art in possession of the present disclosure would recognize as utilizing the LCSs described herein. As illustrated, the client device(s) 202 may be coupled to a network 204 that may be provided by a Local Area Network (LAN), the Internet, combinations thereof, and/or any of network that would be apparent to one of skill in the art in possession of the present disclosure.

As also illustrated in FIG. 2, a plurality of LCS provisioning subsystems 206a, 206b, and up to 206c are coupled to the network 204 such that any or all of those LCS provisioning subsystems 206a-206c may provide LCSs to the client device(s) 202 as discussed in further detail below. In an embodiment, any or all of the LCS provisioning subsystems 206a-206c may include one or more of the IHS 100 discussed above with reference to FIG. 1 and/or may include some or all of the components of the IHS 100. For example, in some of the specific examples provided below, each of the LCS provisioning subsystems 206a-206c may be provided by a respective datacenter or other computing device/computing component location (e.g., a respective one of the “clouds” that enables the “multi-cloud” computing discussed above) in which the components of that LCS provisioning subsystem are included. However, while a specific configuration of the LCS provisioning system 200 (e.g., including multiple LCS provisioning subsystems 206a-206c) is illustrated and described, one of skill in the art in possession of the present disclosure will recognize that other configurations of the LCS provisioning system 200 (e.g., a single LCS provisioning subsystem, LCS provisioning subsystems that span multiple datacenters/computing device/computing component locations, etc.) will fall within the scope of the present disclosure as well.

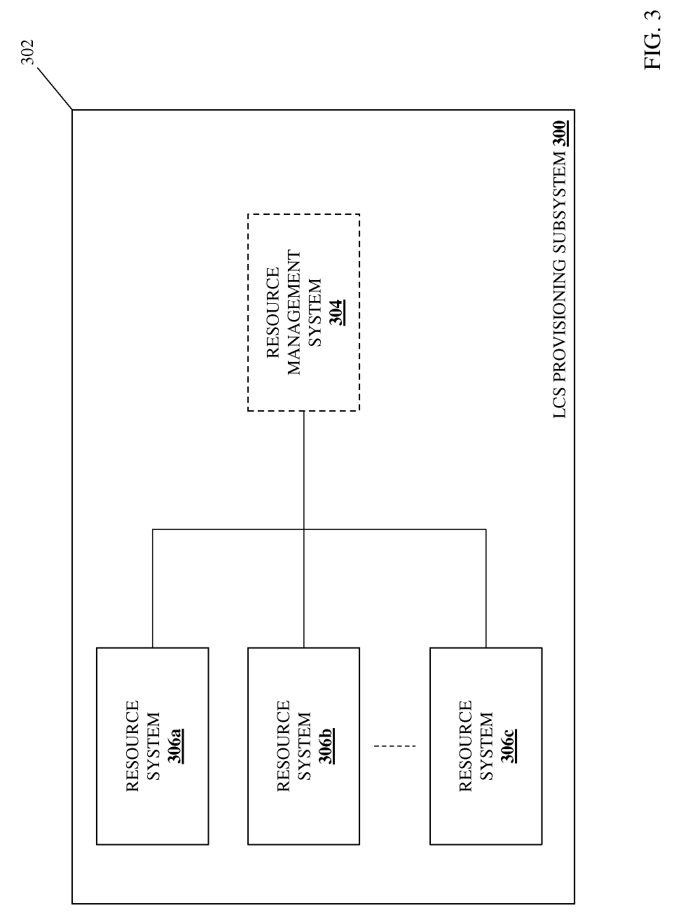

With reference to FIG. 3, an embodiment of an LCS provisioning subsystem 300 is illustrated that may provide any of the LCS provisioning subsystems 206a-206c discussed above with reference to FIG. 2. As such, the LCS provisioning subsystem 300 may include one or more of the IHS 100 discussed above with reference to FIG. 1 and/or may include some or all of the components of the IHS 100, and in the specific examples provided below may be provided by a datacenter or other computing device/computing component location in which the components of the LCS provisioning subsystem 300 are included. However, while a specific configuration of the LCS provisioning subsystem 300 is illustrated and described, one of skill in the art in possession of the present disclosure will recognize that other configurations of the LCS provisioning subsystem 300 will fall within the scope of the present disclosure as well.

In the illustrated embodiment, the LCS provisioning subsystem 300 is provided in a datacenter 302, and includes a resource management system 304 coupled to a plurality of resource systems 306a, 306b, and up to 306c. The resource management system 304 may include a processing system (not illustrated, but that may be provided by a processor that is similar to the processor 102 discussed above with reference to FIG. 1) and a memory system (not illustrated, but which may be similar to the memory 114 discussed above with reference to FIG. 1) that includes instructions that, when executed by the processing system, cause the processing system to provide a resource management engine that is configured to perform the functionality of the resource management engines, resource management subsystems, and/or resource management systems described below. In an embodiment, any of the resource management system 304 and the resource systems 306a-306c may be provided by the IHS 100 discussed above with reference to FIG. 1 and/or may include some or all of the components of the IHS 100. In the specific embodiments provided below, each of the resource management system 304 and the resource systems 306a-306c may include a System Control Processor (SCP) device that may be conceptualized as an “enhanced” SmartNIC device that may be configured to perform functionality that is not available in conventional SmartNIC devices such as, for example, the resource management functionality, LCS provisioning functionality, and/or other SCP functionality described herein.

In an embodiment, any of the resource systems 306a-306c may include any of the resources described below coupled to an SCP device that is configured to facilitate management of those resources by the resource management system 304. Furthermore, the SCP device included in the resource management system 304 may provide an SCP Manager (SCPM) subsystem that is configured to manage the SCP devices in the resource systems 306a-306c, and that performs the functionality of the resource management system 304 described below. In some examples, the resource management system 304 may be provided by a “stand-alone” system (e.g., that is provided in a separate chassis from each of the resource systems 306a-306c), and the SCPM subsystem discussed below may be provided by a dedicated SCP device, processing/memory resources, and/or other components in that resource management system 304. However, in other embodiments, the resource management system 304 may be provided by one of the resource systems 306a-306c (e.g., it may be provided in a chassis of one of the resource systems 306a-306c), and the SCPM subsystem may be provided by an SCP device, processing/memory resources, and/or any other components of that resource system.

As such, the resource management system 304 is illustrated with dashed lines in FIG. 3 to indicate that it may be a stand-alone system in some embodiments, or may be provided by one of the resource systems 306a-306c in other embodiments. Furthermore, one of skill in the art in possession of the present disclosure will appreciate how SCP devices in the resource systems 306a-306c may operate to “elect” or otherwise select one or more of those SCP devices to operate as the SCPM subsystem that provides the resource management system 304 described below. However, while a specific configuration of the LCS provisioning subsystem 300 is illustrated and described, one of skill in the art in possession of the present disclosure will recognize that other configurations of the LCS provisioning subsystem 300 will fall within the scope of the present disclosure as well.

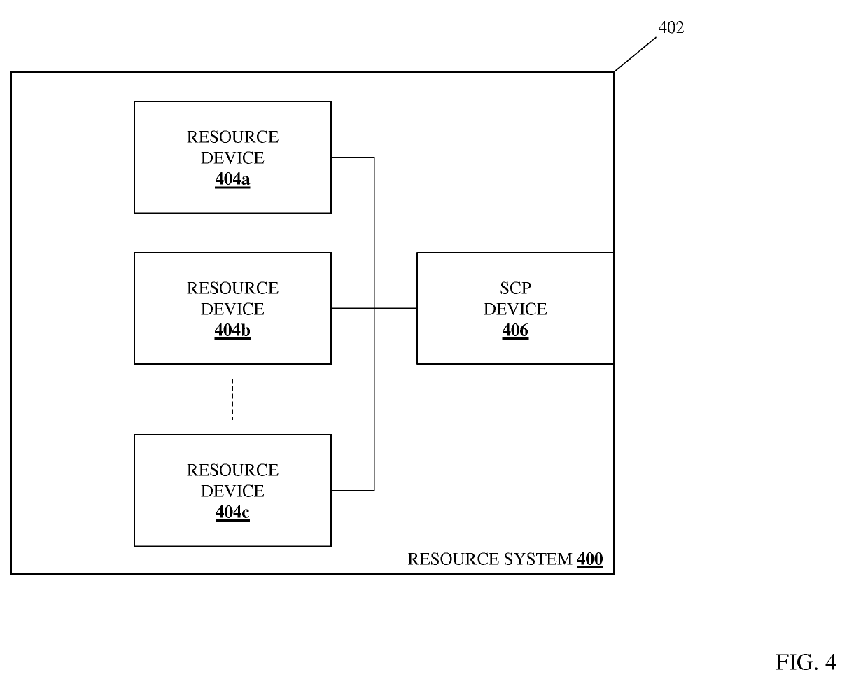

With reference to FIG. 4, an embodiment of a resource system 400 is illustrated that may provide any or all of the resource systems 306a-306c discussed above with reference to FIG. 3. In an embodiment, the resource system 400 may be provided by the IHS 100 discussed above with reference to FIG. 1 and/or may include some or all of the components of the IHS 100. In the illustrated embodiment, the resource system 400 includes a chassis 402 that houses the components of the resource system 400, only some of which are illustrated and discussed below. In the illustrated embodiment, the chassis 402 houses an SCP device 406. In an embodiment, the SCP device 406 may include a processing system (not illustrated, but which may include the processor 102 discussed above with reference to FIG. 1) and a memory system (not illustrated, but which may include the memory 114 discussed above with reference to FIG. 1) that is coupled to the processing system and that includes instructions that, when executed by the processing system, cause the processing system to provide an SCP engine that is configured to perform the functionality of the SCP engines and/or SCP devices discussed below. Furthermore, the SCP device 406 may also include any of a variety of SCP components (e.g., hardware/software) that are configured to enable any of the SCP functionality described below.

In the illustrated embodiment, the chassis 402 also houses a plurality of resource devices 404a, 404b, and up to 404c, each of which is coupled to the SCP device 406. For example, the resource devices 404a-404c may include processing systems (e.g., first type processing systems such as those available from INTEL® Corporation of Santa Clara, California, United States, second type processing systems such as those available from ADVANCED MICRO DEVICES (AMD)® Inc. of Santa Clara, California, United States, Advanced Reduced Instruction Set Computer (RISC) Machine (ARM) devices, Graphics Processing Unit (GPU) devices, Tensor Processing Unit (TPU) devices, Field Programmable Gate Array (FPGA) devices, accelerator devices, etc.); memory systems (e.g., Persistence MEMory (PMEM) devices (e.g., solid state byte-addressable memory devices that reside on a memory bus), etc.); storage devices (e.g., Non-Volatile Memory express over Fabric (NVMe-oF) storage devices, Just a Bunch Of Flash (JBOF) devices, etc.); networking devices (e.g., Network Interface Controller (NIC) devices, etc.); and/or any other devices that one of skill in the art in possession of the present disclosure would recognize as enabling the functionality described as being enabled by the resource devices 404a-404c discussed below. As such, the resource devices 404a-404c in the resource systems 306a-306c/400 may be considered a “pool” of resources that are available to the resource management system 304 for use in composing LCSs.

As described below, any of the resource devise 404a-404c may include or be coupled to a sensor subsystem that is configured to generate operating information that corresponds to the operation of that resource device, with the SCP device 406 configured to transmit that operating information to the resource management system 304 discussed above with reference to FIG. 3. As such, processing device sensors, networking device sensors, memory device sensors, storage device sensors, and/or other sensors may be included in and/or coupled to the resource devices 404a-404c in order to enable the functionality described below.

To provide a specific example, the SCP devices described herein may operate to provide a Root-of-Trust (RoT) for their corresponding resource devices/systems, to provide an intent management engine for managing the workload intents discussed below, to perform telemetry generation and/or reporting operations for their corresponding resource devices/systems, to perform identity operations for their corresponding resource devices/systems, provide an image boot engine (e.g., an operating system image boot engine) for LCSs composed using a processing system/memory system controlled by that SCP device, and/or perform any other operations that one of skill in the art in possession of the present disclosure would recognize as providing the functionality described below. Further, as discussed below, the SCP devices describe herein may include Software-Defined Storage (SDS) subsystems, inference subsystems, data protection subsystems, Software-Defined Networking (SDN) subsystems, trust subsystems, data management subsystems, compression subsystems, encryption subsystems, and/or any other hardware/software described herein that may be allocated to an LCS that is composed using the resource devices/systems controlled by that SCP device. However, while an SCP device is illustrated and described as performing the functionality discussed below, one of skill in the art in possession of the present disclosure will appreciated that functionality described herein may be enabled on other devices while remaining within the scope of the present disclosure as well.

Thus, the resource system 400 may include the chassis 402 including the SCP device 406 connected to any combinations of resource devices. To provide a specific embodiment, the resource system 400 may provide a “Bare Metal Server” that one of skill in the art in possession of the present disclosure will recognize may be a physical server system that provides dedicated server hosting to a single tenant , and thus may include the chassis 402 housing a processing system and a memory system, the SCP device 406, as well as any other resource devices that would be apparent to one of skill in the art in possession of the present disclosure. However, in other specific embodiments, the resource system 400 may include the chassis 402 housing the SCP device 406 coupled to particular resource devices 404a-404c. For example, the chassis 402 of the resource system 400 may house a plurality of processing systems (i.e., the resource devices 404a-404c) coupled to the SCP device 406. In another example, the chassis 402 of the resource system 400 may house a plurality of memory systems (i.e., the resource devices 404a-404c) coupled to the SCP device 406. In another example, the chassis 402 of the resource system 400 may house a plurality of storage devices (i.e., the resource devices 404a-404c) coupled to the SCP device 406. In another example, the chassis 402 of the resource system 400 may house a plurality of networking devices (i.e., the resource devices 404a-404c) coupled to the SCP device 406. However, one of skill in the art in possession of the present disclosure will appreciate that the chassis 402 of the resource system 400 housing a combination of any of the resource devices discussed above will fall within the scope of the present disclosure as well.

As discussed in further detail below, the SCP device 406 in the resource system 400 will operate with the resource management system 304 (e.g., an SCPM subsystem) to allocate any of its resources devices 404a-404c for use in a providing an LCS. Furthermore, the SCP device 406 in the resource system 400 may also operate to allocate SCP hardware and/or perform functionality, which may not be available in a resource device that it has allocated for use in providing an LCS, in order to provide any of a variety of functionality for the LCS. For example, the SCP engine and/or other hardware/software in the SCP device 406 may be configured to perform encryption functionality, compression functionality, and/or other storage functionality known in the art, and thus if that SCP device 406 allocates storage device(s) (which may be included in the resource devices it controls) for use in a providing an LCS, that SCP device 406 may also utilize its own SCP hardware and/or software to perform that encryption functionality, compression functionality, and/or other storage functionality as needed for the LCS as well. However, while particular SCP-enabled storage functionality is described herein, one of skill in the art in possession of the present disclosure will appreciate how the SCP devices 406 described herein may allocate SCP hardware and/or perform other enhanced functionality for an LCS provided via allocation of its resource devices 404a-404c while remaining within the scope of the present disclosure as well.

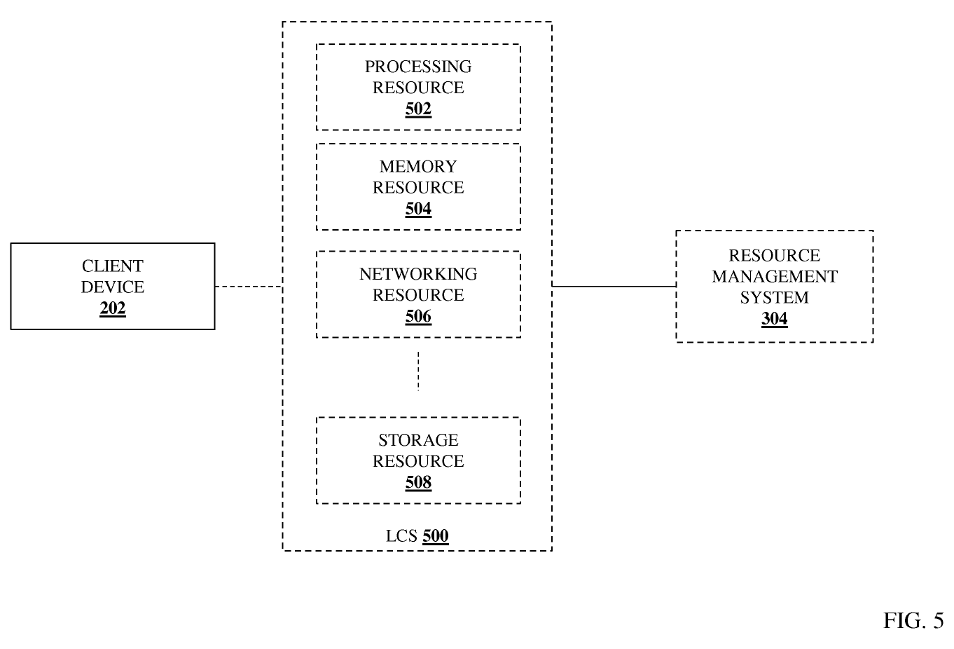

With reference to FIG. 5, an example of the provisioning of an LCS 500 to one of the client device(s) 202 is illustrated. For example, the LCS provisioning system 200 may allow a user of the client device 202 to express a “workload intent” that describes the general requirements of a workload that user would like to perform (e.g., “I need an LCS with 10 gigahertz (Ghz) of processing power and 8 gigabytes (GB) of memory capacity for an application requiring 20 terabytes (TB) of high-performance protected-object-storage for use with a hospital-compliant network”, or “I need an LCS for a machine-learning environment requiring Tensorflow processing with 3 TBs of Accelerator PMEM memory capacity”). As will be appreciated by one of skill in the art in possession of the present disclosure, the workload intent discussed above may be provided to one of the LCS provisioning subsystems 206a-206c, and may be satisfied using resource systems that are included within that LCS provisioning subsystem, or satisfied using resource systems that are included across the different LCS provisioning subsystems 206a-206c.

As such, the resource management system 304 in the LCS provisioning subsystem that received the workload intent may operate to compose the LCS 500 using resource devices 404a-404c in the resource systems 306a-306c/400 in that LCS provisioning subsystem, and/or resource devices 404a-404c in the resource systems 306a-306c/400 in any of the other LCS provisioning subsystems. FIG. 5 illustrates the LCS 500 including a processing resource 502 allocated from one or more processing systems provided by one or more of the resource devices 404a-404c in one or more of the resource systems 306a-306c/400 in one or more of the LCS provisioning subsystems 206a-206c, a memory resource 504 allocated from one or more memory systems provided by one or more of the resource devices 404a-404c in one or more of the resource systems 306a-306c/400 in one or more of the LCS provisioning subsystems 206a-206c, a networking resource 506 allocated from one or more networking devices provided by one or more of the resource devices 404a-404c in one or more of the resource systems 306a-306c/400 in one or more of the LCS provisioning subsystems 206a-206c, and/or a storage resource 508 allocated from one or more storage devices provided by one or more of the resource devices 404a-404c in one or more of the resource systems 306a-306c/400 in one or more of the LCS provisioning subsystems 206a-206c.

Furthermore, as will be appreciated by one of skill in the art in possession of the present disclosure, any of the processing resource 502, memory resource 504, networking resource 506, and the storage resource 508 may be provided from a portion of a processing system (e.g., a core in a processor, a time-slice of processing cycles of a processor, etc.), a portion of a memory system (e.g., a subset of memory capacity in a memory device), a portion of a storage device (e.g., a subset of storage capacity in a storage device), and/or a portion of a networking device (e.g., a portion of the bandwidth of a networking device). Further still, as discussed above, the SCP device(s) 406 in the resource systems 306a-306c/400 that allocate any of the resource devices 404a-404c that provide the processing resource 502, memory resource 504, networking resource 506, and the storage resource 508 in the LCS 500 may also allocate their SCP hardware and/or perform enhanced functionality (e.g., the enhanced storage functionality in the specific examples provided above) for any of those resources that may otherwise not be available in the processing system, memory system, storage device, or networking device allocated to provide those resources in the LCS 500.

With the LCS 500 composed using the processing resources 502, the memory resources 504, the networking resources 506, and the storage resources 508, the resource management system 304 may provide the client device 202 resource communication information such as, for example, Internet Protocol (IP) addresses of each of the systems/devices that provide the resources that make up the LCS 500, in order to allow the client device 202 to communicate with those systems/devices in order to utilize the resources that make up the LCS 500. As will be appreciated by one of skill in the art in possession of the present disclosure, the resource communication information may include any information that allows the client device 202 to present the LCS 500 to a user in a manner that makes the LCS 500 appear the same as an integrated physical system having the same resources as the LCS 500.

Thus, continuing with the specific example above in which the user provided the workload intent defining an LCS with a 10 Ghz of processing power and 8 GB of memory capacity for an application with 20 TB of high-performance protected object storage for use with a hospital-compliant network, the processing resources 502 in the LCS 500 may be configured to utilize 10 Ghz of processing power from processing systems provided by resource device(s) in the resource system(s), the memory resources 504 in the LCS 500 may be configured to utilize 8 GB of memory capacity from memory systems provided by resource device(s) in the resource system(s), the storage resources 508 in the LCS 500 may be configured to utilize 20 TB of storage capacity from high-performance protected-object-storage storage device(s) provided by resource device(s) in the resource system(s), and the networking resources 506 in the LCS 500 may be configured to utilize hospital-compliant networking device(s) provided by resource device(s) in the resource system(s).

Similarly, continuing with the specific example above in which the user provided the workload intent defining an LCS for a machine-learning environment for Tensorflow processing with 3 TBs of Accelerator PMEM memory capacity, the processing resources 502 in the LCS 500 may be configured to utilize TPU processing systems provided by resource device(s) in the resource system(s), and the memory resources 504 in the LCS 500 may be configured to utilize 3 TB of accelerator PMEM memory capacity from processing systems/memory systems provided by resource device(s) in the resource system(s), while any networking/storage functionality may be provided for the networking resources 506 and storage resources 508, if needed.

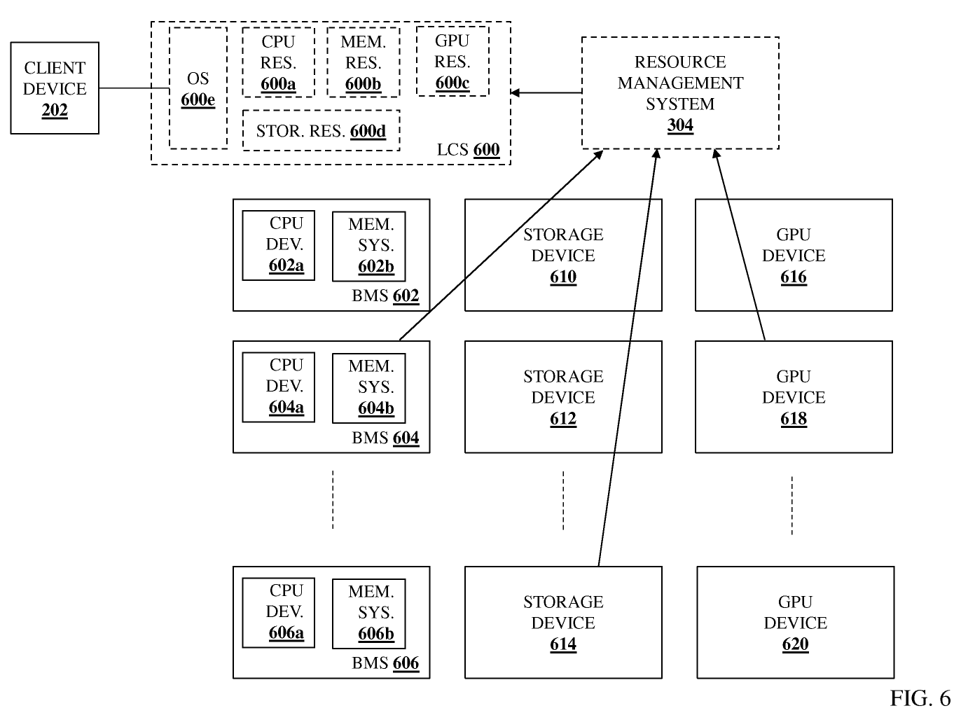

With reference to FIG. 6, another example of the provisioning of an LCS 600 to one of the client device(s) 202 is illustrated. As will be appreciated by one of skill in the art in possession of the present disclosure, many of the LCSs provided by the LCS provisioning system 200 will utilize a “compute” resource (e.g., provided by a processing resource such as an x86 processor, an AMD processor, an ARM processor, and/or other processing systems known in the art, along with a memory system that includes instructions that, when executed by the processing system, cause the processing system to perform any of a variety of compute operations known in the art), and in many situations those compute resources may be allocated from a Bare Metal Server (BMS) and presented to a client device 202 user along with storage resources, networking resources, other processing resources (e.g., GPU resources), and/or any other resources that would be apparent to one of skill in the art in possession of the present disclosure.

As such, in the illustrated embodiment, the resource systems 306a-306c available to the resource management system 304 include a Bare Metal Server (BMS) 602 having a Central Processing Unit (CPU) device 602a and a memory system 602b, a BMS 604 having a CPU device 604a and a memory system 604b, and up to a BMS 606 having a CPU device 606a and a memory system 606b. Furthermore, one or more of the resource systems 306a-306c includes resource devices 404a-404c provided by a storage device 610, a storage device 612, and up to a storage device 614. Further still, one or more of the resource systems 306a-306c includes resource devices 404a-404c provided by a Graphics Processing Unit (GPU) device 616, a GPU device 618, and up to a GPU device 620.

FIG. 6 illustrates how the resource management system 304 may compose the LCS 600 using the BMS 604 to provide the LCS 600 with CPU resources 600a that utilize the CPU device 604a in the BMS 604, and memory resources 600b that utilize the memory system 604b in the BMS 604. Furthermore, the resource management system 304 may compose the LCS 600 using the storage device 614 to provide the LCS 600 with storage resources 600d, and using the GPU device 318 to provide the LCS 600 with GPU resources 600c. As illustrated in the specific example in FIG. 6, the CPU device 604a and the memory system 604b in the BMS 604 may be configured to provide an operating system 600e that is presented to the client device 202 as being provided by the CPU resources 600a and the memory resources 600b in the LCS 600, with operating system 600e utilizing the GPU device 618 to provide the GPU resources 600c in the LCS 600, and utilizing the storage device 614 to provide the storage resources 600d in the LCS 600. The user of the client device 202 may then provide any application(s) on the operating system 600e provided by the CPU resources 600a/CPU device 604a and the memory resources 600b/memory system 604b in the LCS 600/BMS 604, with the application(s) operating using the CPU resources 600a/CPU device 604a, the memory resources 600b/memory system 604b, the GPU resources 600c/GPU device 618, and the storage resources 600d/storage device 614.

Furthermore, as discussed above, the SCP device(s) 406 in the resource systems 306a-306c/400 that allocates any of the CPU device 604a and memory system 604b in the BMS 604 that provide the CPU resource 600a and memory resource 600b, the GPU device 618 that provides the GPU resource 600c, and the storage device 614 that provides storage resource 600d, may also allocate SCP hardware and/or perform enhanced functionality (e.g., the enhanced storage functionality in the specific examples provided above) for any of those resources that may otherwise not be available in the CPU device 604a, memory system 604b, storage device 614, or GPU device 618 allocated to provide those resources in the LCS 500.

However, while simplified examples are described above, one of skill in the art in possession of the present disclosure will appreciate how multiple devices/systems (e.g., multiple CPUs, memory systems, storage devices, and/or GPU devices) may be utilized to provide an LCS. Furthermore, any of the resources utilized to provide an LCS (e.g., the CPU resources, memory resources, storage resources, and/or GPU resources discussed above) need not be restricted to the same device/system, and instead may be provided by different devices/systems over time (e.g., the GPU resources 600c may be provided by the GPU device 618 during a first time period, by the GPU device 616 during a second time period, and so on) while remaining within the scope of the present disclosure as well. Further still, while the discussions above imply the allocation of physical hardware to provide LCSs, one of skill in the art in possession of the present disclosure will recognize that the LCSs described herein may be composed similarly as discussed herein from virtual resources. For example, the resource management system 304 may be configured to allocate a portion of a logical volume provided in a Redundant Array of Independent Disk (RAID) system to an LCS, allocate a portion/time-slice of GPU processing performed by a GPU device to an LCS, and/or perform any other virtual resource allocation that would be apparent to one of skill in the art in possession of the present disclosure in order to compose an LCS.

Similarly as discussed above, with the LCS 600 composed using the CPU resources 600a, the memory resources 600b, the GPU resources 600c, and the storage resources 600d, the resource management system 304 may provide the client device 202 resource communication information such as, for example, Internet Protocol (IP) addresses of each of the systems/devices that provide the resources that make up the LCS 600, in order to allow the client device 202 to communicate with those systems/devices in order to utilize the resources that make up the LCS 600. As will be appreciated by one of skill in the art in possession of the present disclosure, the resource communication information allows the client device 202 to present the LCS 600 to a user in a manner that makes the LCS 600 appear the same as an integrated physical system having the same resources as the LCS 600.

As will be appreciated by one of skill in the art in possession of the present disclosure, the LCS provisioning system 200 discussed above solves issues present in conventional Information Technology (IT) infrastructure systems that utilize “purpose-built” devices (server devices, storage devices, etc.) in the performance of workloads and that often result in resources in those devices being underutilized. This is accomplished, at least in part, by having the resource management system(s) 304 “build” LCSs that satisfy the needs of workloads when they are deployed. As such, a user of a workload need simply define the needs of that workload via a “manifest” expressing the workload intent of the workload, and resource management system 304 may then compose an LCS by allocating resources that define that LCS and that satisfy the requirements expressed in its workload intent, and present that LCS to the user such that the user interacts with those resources in same manner as they would physical system at their location having those same resources.

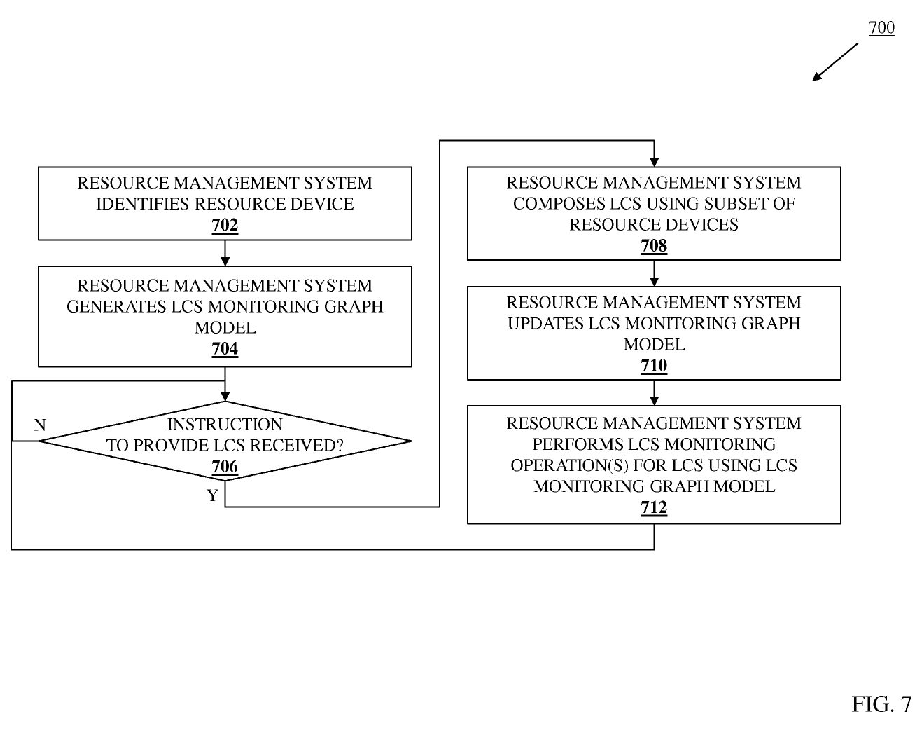

Referring now to FIG. 7, an embodiment of a method 700 for monitoring an LCS using graph modeling is illustrated. As discussed below, the systems and methods of the present disclosure provide a graph model that may be used to monitor the operation of an LCS that has been composed using a plurality of resource devices. The graph-modeling-based LCS monitoring system of the present disclosure may include a resource management system coupled to resource devices. The resource management system identifies the resource devices and generates an LCS monitoring graph model with resource device nodes identifying the resource devices, and respective resource operation nodes connected via edges to those resource device nodes and configured to identify a current operation of their identified resource devices. The resource management system then composes an LCS using a first subset of the resource devices and, in response, updates the LCS monitoring graph model to include an LCS node that identifies the LCS and that is connected to the resource device nodes identifying the first subset of the resource devices. The resource management system then uses information identified from respective resource operation node(s) connected to the resource device nodes identifying the first subset of the resource devices to perform LCS monitoring operation(s) for the LCS. As such, relatively low-level, real-time monitoring of LCSs may be performed to understand and report the operations of the resource devices providing the LCS, enable the billing of the utilization of any particular resource devices, forecast the future use of resource devices for LCSs, remediate configuration “drifts” by resource devices that provide LCSs, and/or provide other monitoring benefits that would be apparent to one of skill in the art in possession of the present disclosure.

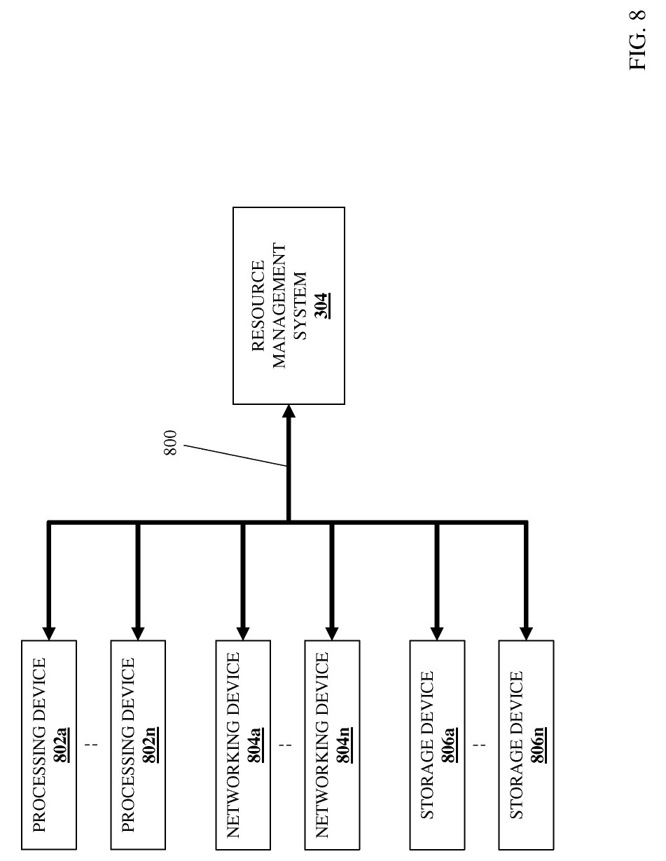

The method 700 begins at block 702 where a resource management system identifies resource devices. In an embodiment, at block 702, the resource management system 304 in the LCS provisioning subsystem 300 discussed above with reference to FIG. 3 may be powered on, booted, reset, rebooted, and/or otherwise initialized and, in response, the resource management system 304 in the LCS provisioning subsystem 300 may perform resource device identification operations that include identifying the resource devices 404a-404c in the resource systems 306a-306c/400 that are coupled to the resource management system 304. With reference to FIG. 8, a specific example of resource device identification operations 800 are illustrated that provide for the identification of a plurality of processing devices 802a-802n (which may be included in the resource devices 404a-404c of the resource systems 306a-306c/400 that are coupled to the resource management system 304), a plurality of networking devices 804a-804n (which may be included in the resource devices 404a-404c of the resource systems 306a-306c/400 that are coupled to the resource management system 304), and a plurality of storage devices 806a-806n (which may be included in the resource devices 404a-404c of the resource systems 306a-306c/400 that are coupled to the resource management system 304). However, while processing devices, networking devices, and storage devices are illustrated and described in the simplified examples provided below, one of skill in the art in possession of the present disclosure will appreciate how any other resource devices may be identified at block 702 while remaining within the scope of the present disclosure as well.

The method 700 then proceeds to block 704 where the resource management system generates an LCS monitoring graph model. In an embodiment, at block 704, the resource management system 304 may perform LCS monitoring graph model generation operations that include generating an LCS monitoring graph model that includes a respective resource device graph model node for each resource device that was identified at block 702, with each respective resource device graph model node connected via a respective edge to a plurality of resource information graph models nodes that are configured to identify information about the resource device identified by that respective resource device graph model node (e.g., the resource capability graph model nodes that identify capabilities of resource devices, the resource operation graph model nodes that identify the operation of resource devices, and the resource policy graph model nodes that identify policies for resource devices in the examples below).

The LCS monitoring graph model may be stored entirely in memory (or other storage) in the resource management system 304. However, in some embodiments, subgraphs of the LCS monitoring graph model may be stored by agents on the resource systems 306a-306c that include the resource devices identified in the LCS monitoring graph model, with those agents tracking changes to the their resource devices to update their subgraphs of the LCS monitoring graph model, enforcing local policies in their resource system, and/or performing other local operations that would be apparent to one of skill in the art in possession of the present disclosure. As such, the resource management system 304 may operate as a “centralized” LCS monitoring system using the LCS monitoring graph model, with agents provided on distributed resource systems updating their subgraphs and synchronizing the subgraphs with the resource management system 304, while performing state management, policy enforcement, and/or other local operations on their resource systems.

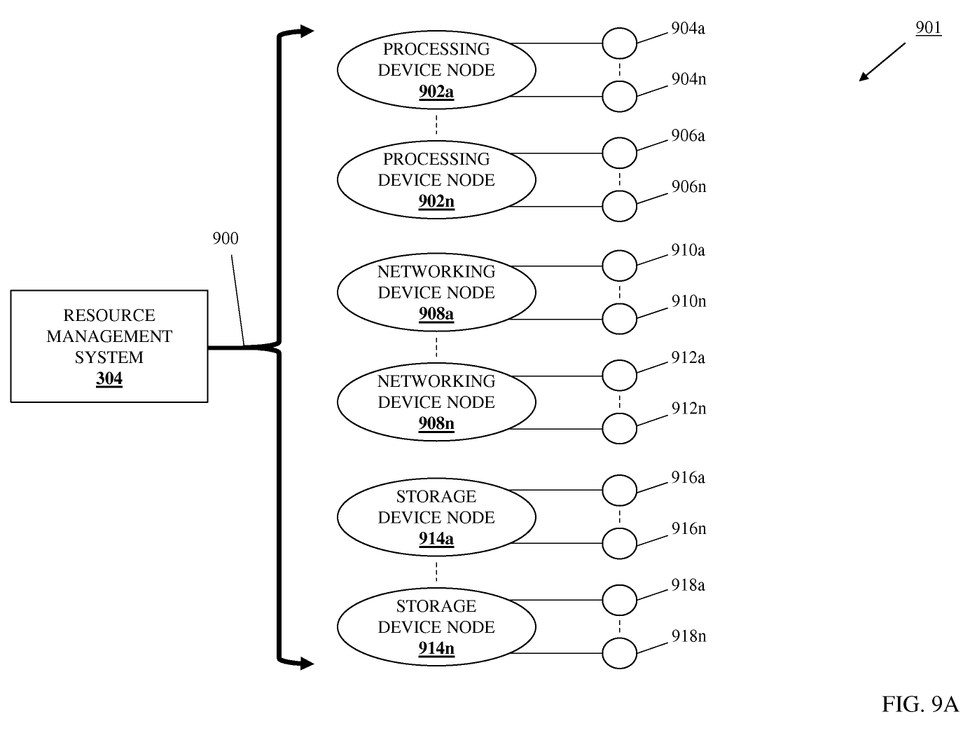

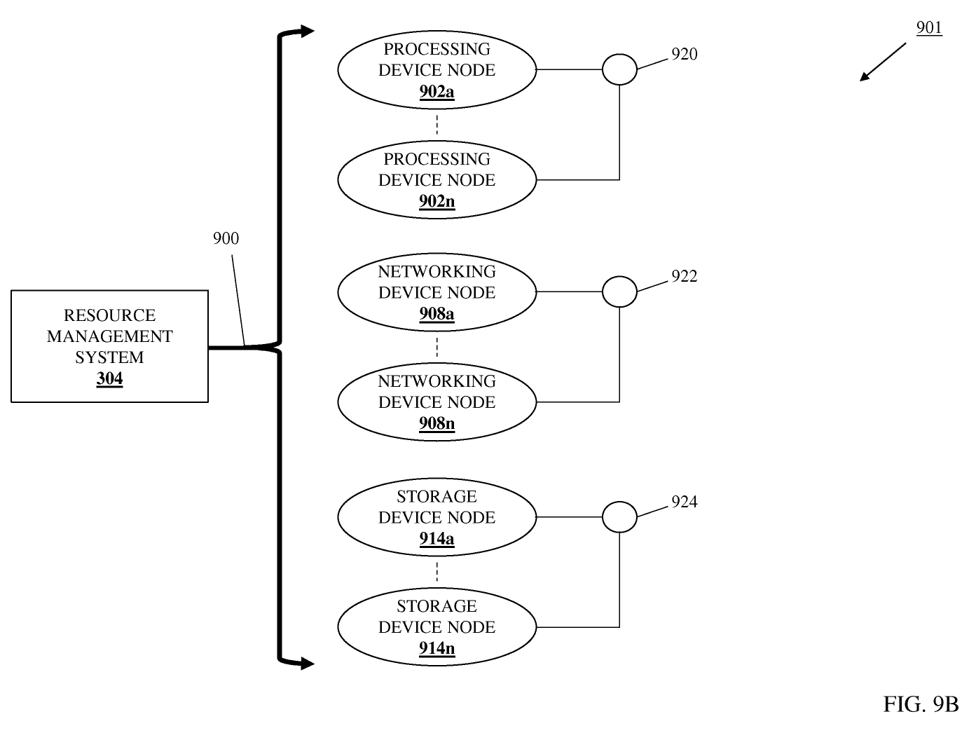

With reference to FIG. 9A, a specific example of LCS monitoring graph model generation operations 900 by the resource management system 304 are illustrated that provide for the generation of an LCS monitoring graph model 901 that includes a respective processing device node 902a-902n for each of the processing devices 802a-802n that were identified at block 702. Furthermore, the LCS monitoring graph model 901 also includes a plurality of processing device information nodes 904a-904n that are each connected to the processing device node 902a by a respective edge, and a plurality of processing device information nodes 906a-906n that are each connected to the processing device node 902n by a respective edge. As described in further detail below, the processing device information nodes 904a-904n may each be configured to identify information about the processing device 802a identified by the processing device node 902a, and the processing device information nodes 906a-906n may each be configured to identify information about the processing device 802n identified by the processing device node 902n.

For example, any of the processing device information nodes may be processing device capability nodes that are configured to identify processing device capability information that describes capabilities of that processing device (e.g., a processing speed of that processing device, a processing power required for that processing device, and/or any other processing device capabilities that would be apparent one of skill in the art in possession of the present disclosure). In another example, any of the processing device information nodes may be processing device operation nodes that are configured to identify processing device operating information that is configured to describe the current operation of that processing device (e.g., a processing bandwidth currently being used by that processing device, a processing power currently being consumed by that processing device, and/or any other processing device operating information that would be apparent one of skill in the art in possession of the present disclosure). In yet another example, any of the processing device information nodes may be processing device policy nodes that are configured to identify processing device policy information that describes policies for using that processing device (e.g., a maximum processing bandwidth that should be used by that processing device, a maximum processing power that should be used by that processing device, and/or any other processing device policies that would be apparent one of skill in the art in possession of the present disclosure).

As such, the processing device information nodes may be configured to identify static processing device information (e.g., the processing device capabilities information discussed above) or dynamic processing device information (e.g., the processing device operating information discussed above that may be retrieved from sensor(s) coupled to that processing device and updated in real-time in the processing device information node(s)), and may be user specific and/or updatable (e.g., the processing device policy information discussed above may be specific to particular users and/or may be updated for users as policies for those users change). As such, the generation of the LCS monitoring graph model 901 may include retrieving any information about a processing device identified by a processing device node and populating that information in the processing device information node(s) connected to that processing device node, linking processing device information node(s) connected to a processing device node to sensor(s) that report information about the processing device identified by that processing device node, and/or any other operations that one of skill in the art in possession of the present disclosure would recognize as enabling the functionality using the LCS monitoring graph models described below. However, while specific examples of processing device information identified by processing device information nodes has been described, one of skill in the art in possession of the present disclosure will appreciate how the processing device information nodes of the present disclosure may identify any information about a processing device while remaining within the scope of the present disclosure.

With continued reference to FIG. 9A, the LCS monitoring graph model 901 also includes a respective networking device node 908a-908n for each of the networking devices 804a-804n that were identified at block 702. Furthermore, the LCS monitoring graph model 901 also includes a plurality of networking device information nodes 910a-910n that are each connected to the networking device node 908a by a respective edge, and a plurality of networking device information nodes 912a-912n that are each connected to the networking device node 908n by a respective edge. As described in further detail below, the processing device information nodes 910a-910n may each be configured to identify information about the networking device 804a identified by the networking device node 908a, and the networking device information nodes 912a-912n may each be configured to identify information about the networking device 804n identified by the networking device node 908n.

For example, any of the networking device information nodes may be networking device capability nodes that are configured to identify networking device capability information that describes capabilities of that networking device (e.g., a networking speed of that networking device, a networking power required for that networking device, and/or any other networking device capabilities that would be apparent one of skill in the art in possession of the present disclosure). In another example, any of the networking device information nodes may be networking device operation nodes that are configured to identify networking device operating information that is configured to describe the current operation of that networking device (e.g., a networking bandwidth currently being used by that networking device, a networking power currently being consumed by that networking device, and/or any other networking device operating information that would be apparent one of skill in the art in possession of the present disclosure). In yet another example, any of the networking device information nodes may be networking device policy nodes that are configured to identify networking device policy information that describes policies for using that networking device (e.g., a maximum networking bandwidth that should be used by that networking device, a maximum networking power that should be used by that networking device, and/or any other networking device policies that would be apparent one of skill in the art in possession of the present disclosure).

As such, the networking device information nodes may be configured to identify static networking device information (e.g., the networking device capabilities information discussed above) or dynamic networking device information (e.g., the networking device operating information discussed above that may be retrieved from sensor(s) coupled to that networking device and updated in real-time in the networking device information node(s)), and may be user specific and/or updatable (e.g., the networking device policy information discussed above may be specific to particular users and/or may be updated for users as policies for those users change). As such, the generation of the LCS monitoring graph model 901 may include retrieving any information about a networking device identified by a networking device node and populating that information in the networking device information node(s) connected to that networking device node, linking networking device information node(s) connected to a networking device node to sensor(s) that report information about the networking device identified by that networking device node, and/or any other operations that one of skill in the art in possession of the present disclosure would recognize as enabling the functionality using the LCS monitoring graph models described below. However, while specific examples of networking device information identified by networking device information nodes has been described, one of skill in the art in possession of the present disclosure will appreciate how the networking device information nodes of the present disclosure may identify any information about a networking device while remaining within the scope of the present disclosure.

With continued reference to FIG. 9A, the LCS monitoring graph model 901 also includes a respective storage device node 914a-914n for each of the networking devices 806a-806n that were identified at block 702. Furthermore, the LCS monitoring graph model 901 also includes a plurality of storage device information nodes 916a-916n that are each connected to the storage device node 914a by a respective edge, and a plurality of storage device information nodes 918a-918n that are each connected to the storage device node 914n by a respective edge. As described in further detail below, the storage device information nodes 916a-916n may each be configured to identify information about the storage device 806a identified by the storage device node 914a, and the storage device information nodes 918a-918n may each be configured to identify information about the storage device 806n identified by the storage device node 914n.

For example, any of the storage device information nodes may be storage device capability nodes that are configured to identify storage device capability information that describes capabilities of that storage device (e.g., a storage speed of that storage device, a storage power required for that storage device, and/or any other storage device capabilities that would be apparent one of skill in the art in possession of the present disclosure). In another example, any of the storage device information nodes may be storage device operation nodes that are configured to identify storage device operating information that is configured to describe the current operation of that storage device (e.g., a storage bandwidth currently being used by that storage device, a storage power currently being consumed by that storage device, and/or any other storage device operating information that would be apparent one of skill in the art in possession of the present disclosure). In yet another example, any of the storage device information nodes may be storage device policy nodes that are configured to identify storage device policy information that describes policies for using that storage device (e.g., a maximum storage bandwidth that should be used by that storage device, a maximum storage power that should be used by that storage device, and/or any other storage device policies that would be apparent one of skill in the art in possession of the present disclosure).

As such, the storage device information nodes may be configured to identify static storage device information (e.g., the storage device capabilities information discussed above) or dynamic storage device information (e.g., the storage device operating information discussed above that may be retrieved from sensor(s) coupled to that storage device and updated in real-time in the storage device information node(s)), and may be user specific and/or updatable (e.g., the storage device policy information discussed above may be specific to particular users and/or may be updated for users as policies for those users change). As such, the generation of the LCS monitoring graph model 901 may include retrieving any information about a storage device identified by a storage device node and populating that information in the storage device information node(s) connected to that storage device node, linking storage device information node(s) connected to a storage device node to sensor(s) that report information about the storage device identified by that storage device node, and/or any other operations that one of skill in the art in possession of the present disclosure would recognize as enabling the functionality using the LCS monitoring graph models described below. However, while specific examples of storage device information identified by storage device information nodes has been described, one of skill in the art in possession of the present disclosure will appreciate how the storage device information nodes of the present disclosure may identify any information about a storage device while remaining within the scope of the present disclosure.

While each of the processing device nodes 902a-902n, the networking device nodes 908a-908n, and the storage device nodes 914a-914n are illustrated as including “dedicated” processing device information nodes, networking device information nodes, and storage device information nodes, respectively, one of skill in the art in possession of the present disclosure will appreciate how resource device graph model nodes may share resource information graph model nodes while remaining within the scope of the present disclosure as well. For example, as illustrated in FIG. 9B, the LCS monitoring graph model 901 may include a processing device information node 920 that may be connected to any subset of the processing device nodes 902a-902n by respective edges, a networking device information node 922 that may be connected to any subset of the networking device nodes 908a-908n by respective edges, and a storage device information node 924 that may be connected to any of the storage device nodes 914a-914n by respective edges.

As will be appreciated by one of skill in the art in possession of the present disclosure, the “shared” processing device information node 920 may be configured to identify information that is common to the processing device 802a-802n identified by the processing device nodes 902a-902n that are connected to the processing device information node 920 (e.g., the processing device information node 920 may identify “x86” processing devices). Similarly, the “shared” networking device information node 922 may be configured to identify information that is common to the networking device 804a-804n identified by the networking device nodes 908a-908n that are connected to the networking device information node 922 (e.g., the networking device information node 922 may identify networking devices with a minimum bandwidth). Similarly, the “shared” storage device information node 924 may be configured to identify information that is common to the storage device 806a-806n identified by the storage device nodes 914a-914n that are connected to the storage device information node 924 (e.g., the storage device information node 924 may identify storage devices with a minimum storage capacity).

As will be appreciated by one of skill in the art in possession of the present disclosure, the resource management system 304 may be configured to monitor is connected resource devices to identify when resource devices are disconnected from (or otherwise unavailable to) the resource management system 304, or when “new” resource devices are connected to (or become available to) the resource management 304, and in response, update the LCS monitoring graph model 901 to remove resource device graph model nodes (and their resource information graph model nodes) for the disconnected resource devices, and add resource device graph model nodes (and corresponding resource information graph model nodes) for connected resource devices. As such, the LCS monitoring graph model 901 may be provided by a dynamically updated “digital twin” of the LCS provisioning subsystem 300 that digitally identifies the connective state of the resource management system 304 with respect to its connected resource devices. Furthermore, while a specific LCS monitoring graph model has been illustrated and described, one of skill in the art in possession of the present disclosure will appreciate how LCS monitoring graph models provided according to the teachings of the present disclosure may include a variety of configurations for digitally modeling the resource devices that are available to a resource management system for providing an LCS as described in further detail below.

The method 700 then proceeds to decision block 706 where the method 700 proceeds depending on whether an instruction to provide an LCS is received. As discussed above, following its initialization and discovery of resource devices, the resource management system 304 may receive an instruction to provide an LCS that is generated and provided to the resource management system 304 in response to a user expressing a workload intent to the LCS provisioning subsystem 300. As such, at decision block 706, the method 700 will proceed depending on whether such an instruction is received by the resource management system 304. If, at decision block 706, no instruction to provide an LCS is received, the method 700 returns to decision block 706. As such, the method 700 may loop such that that resource management system 304 monitors for an instruction to provide an LCS, and as discussed above the resource management system 304 may discover “new” resource devices and add them to the LCS monitoring graph model 901 when those resource devices are coupled to the resource management system 304, remove “old” resource devices from the LCS monitoring graph model 901 when those resource devices are decoupled or otherwise become unavailable to the resource management system 304, and/or perform other LCS monitoring graph model operations while looping through decision block 706.

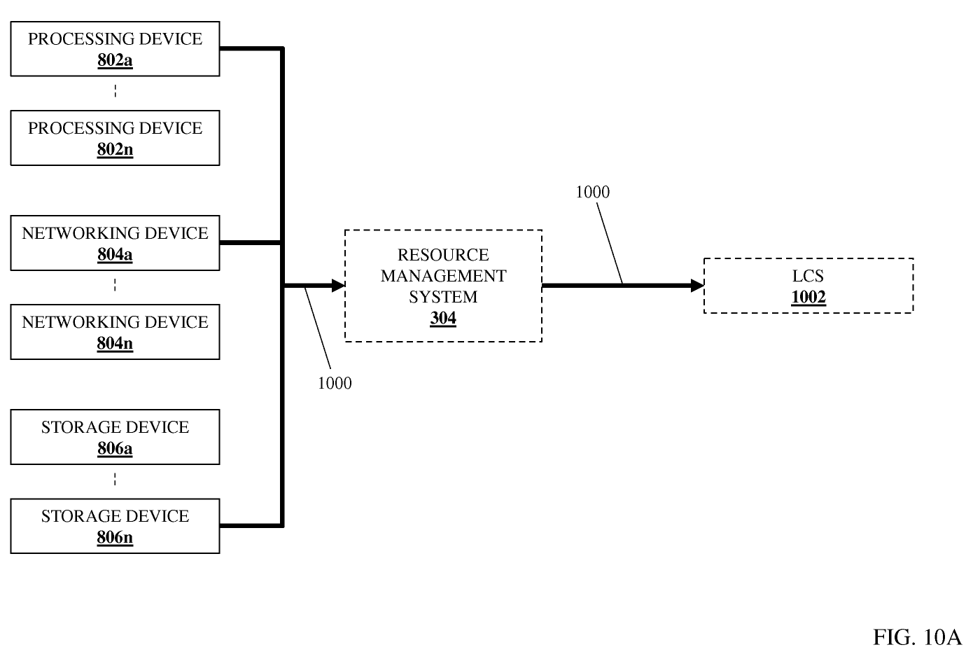

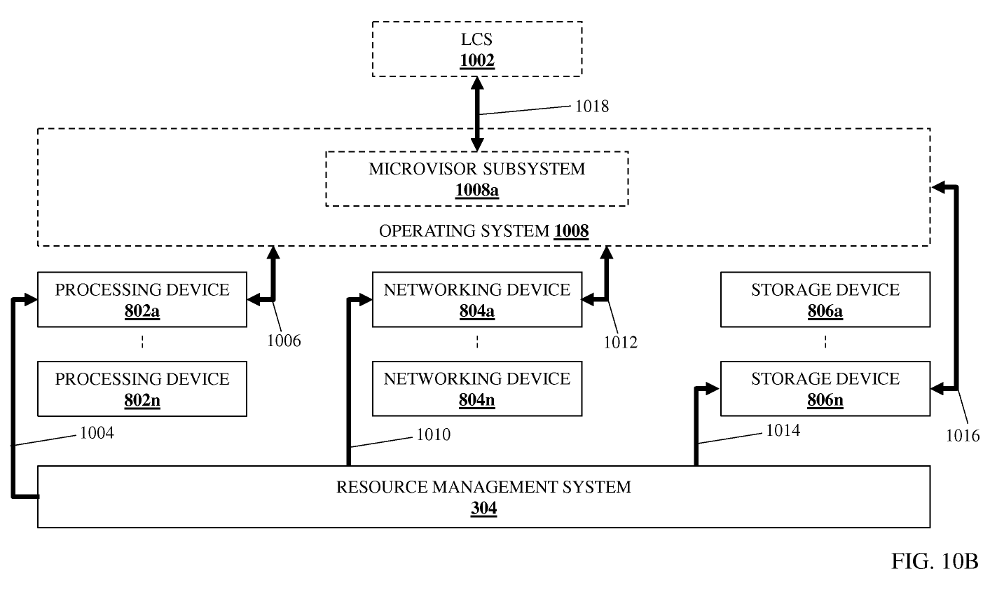

If, at decision block 706, an instruction to provide an LCS is received, the method 700 proceeds to block 708 where the resource management system composes an LCS using a subset of the resource devices. In an embodiment, at decision block 706, the resource management system 304 may receive an instruction to provide an LCS that may have been generated based on a workload intent expressed by a user as described above and, in response, may compose an LCS using its available resource devices to satisfy that workload intent. For example, with reference to FIG. 10A, in response to receiving an instruction to provide an LCS, the resource management system 304 may perform LCS composition operations 1000 that include composing an LCS 1002 using the processing device 802a, the networking device 804a, and the storage device 806n.

For example, as illustrated in FIG. 10B, the LCS composition operations 1000 performed by the resource management system 304 may include processing device configuration operations 1004 that configure the processing device 802a to perform processing operations 1006 to provide the LCS 1002 (e.g., in cooperation with an operating system 1008 including a microvisor subsystem 1008a that is provided using any of the processing devices 802a-802n (and corresponding memory devices, not illustrated) available to the resource management system 304 in, for example, one of the BMSs discussed above), networking device configuration operations 1010 that configure the networking device 804a to perform networking operations 1012 to provide networking for the LCS 1002 (e.g., by transmitting data to and from the LCS 1002), and storage device configuration operations 1014 that configure the storage device 806n to perform storage operations 1016 to provide storage for the LCS 1002 (e.g., by storing data utilized by\ the LCS 1002). The microvisor subsystem 1008a in the operating system 1008 may then operate using the processing device 802a, the networking device 804a, and the storage device 806n to perform LCS provisioning operations 1018 to provide the LCS 1002. However, while the composition of an LCS using the simplified example of resource devices provided by the processing devices 802a-802n, networking devices 804a-804n, and storage devices 806a-806n is provided herein, one of skill in the art in possession of the present disclosure will appreciate how LCSs may be composed using a variety of resource devices while remaining within the scope of the present disclosure as well.

The method 700 then proceeds to block 710 where the resource management system updates the LCS monitoring graph model. In an embodiment, at block 710 and in response to composing the LCS at block 708, the resource management system 304 may perform LCS monitoring graph model update operations that include updating the LCS monitoring graph model generated at block 704 to include an LCS graph model node for the LCS that was composed at block 708, with the LCS graph model node connected via a respective edge to a subset of the resource device graph models nodes that identify the resource devices that are being used to provide that LCS, and connected via a respective edge to a plurality of LCS information graph model nodes that are configured to identify information about the LCS identified by the LCS graph model node (e.g., LCS capability graph model nodes that identify capabilities of LCSs, LCS operation graph model nodes that identify the operation of LCSs, and LCS policy graph model nodes that identify policies for LCSs in the examples below).

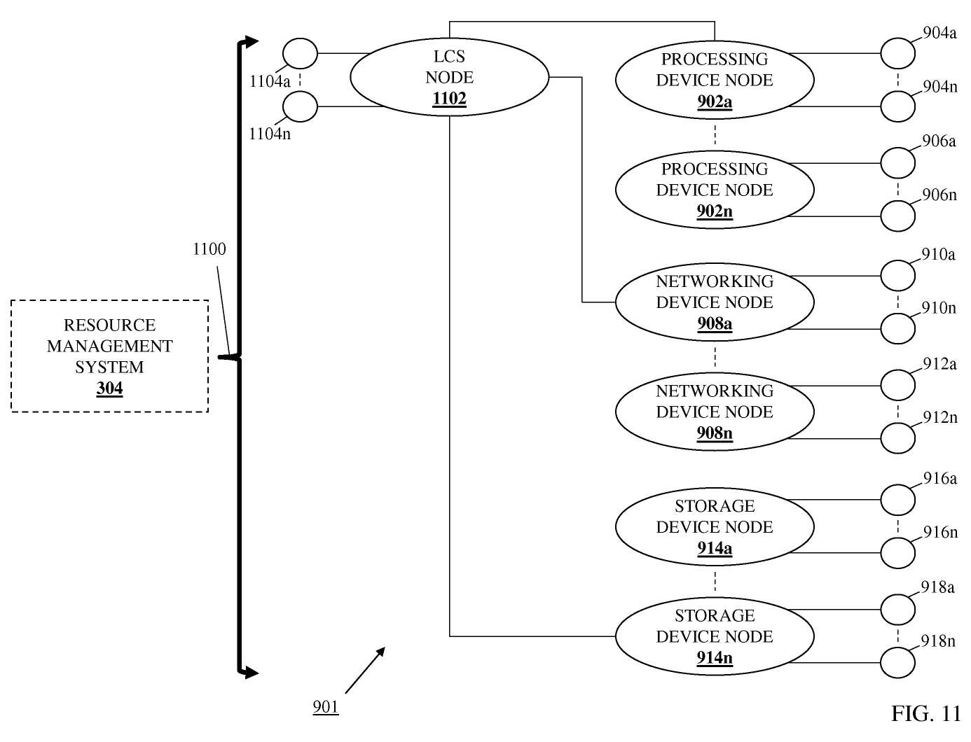

For example, with reference to FIG. 11, a specific example of LCS monitoring graph model update operations 1100 by the resource management system 304 are illustrated that provide for the updating of the LCS monitoring graph model 901 to include an LCS node 1102 for the LCS 1002 that was composed at block 708. Furthermore, the LCS monitoring graph model 901 is also updated to provide an edge that connects the LCS node 1102 to the processing device node 902a that identifies the processing device 802a that was used to compose the LCS 1002, an edge that connects the LCS node 1102 to the networking device node 908a that identifies the networking device 804a that was used to compose the LCS 1002, and an edge that connects the LCS node 1102 to the storage device node 914n that identifies the storage device 806n that was used to compose the LCS 1002. Further still, the LCS monitoring graph model 901 is also updated to include a plurality of LCS information nodes 1104a-1104n that are each connected to the LCS node 1102 by a respective edge. As described in further detail below, the LCS information nodes 1104a-1104n may each be configured to identify information about the LCS 1002 identified by the LCS node 1102.

For example, any of the LCS information nodes 1104a-1104n may be LCS capability nodes that are configured to identify LCS capability information that describes capabilities of the LCS 1002 (e.g., system capabilities such as database provisioning capabilities, vector database provisioning capabilities, static web server provisioning capabilities, object storage provisioning capabilities, file hierarchical storage provisioning capabilities, and data movement (e.g., Direct Memory Access (DMA) provisioning capabilities; Artificial Intelligence (AI) capabilities such as Retrieval-Augmented Generation (RAG) Model (“XYZ”) provisioning capabilities, and Large Language Model (LLM) implementation provisioning capabilities; security capabilities such as OpenID Connect (OIDC) Authentication Connector provisioning capabilities, OpenTelemetry (OTEL) Trace Collector provisioning capabilities, Certificate Authority (CA) Verification provisioning capabilities, and Data Inspection Proxy provisioning capabilities; Quality of Service (QoS) provisioning capabilities that provide performance, scalability, availability, and serviceability needs for LCSs, and/or any other LCS capabilities that would be apparent one of skill in the art in possession of the present disclosure).

In another example, any of the LCS information nodes 1104a-1104n may be LCS operation nodes that are configured to identify LCS operating information that is configured to describe the current operation of the LCS 1002 (e.g., currently present and/or enabled capabilities for the LCS 1002, capability dependencies (e.g., name and version) required for the LCS 1002, configuration metadata for the LCS 1002, an Internet Protocol (IP) address for the LCS 1002, a name of the LCS 1002, a cryptographic or otherwise unique identification for the LCS 1002, credentials and account information for the LCS 1002, tenant owner information for the LCS 1002, LCS runtime policy information for the LCS 1002, and/or any other LCS operating information that would be apparent one of skill in the art in possession of the present disclosure).

In yet another example, any of the LCS information nodes 1104a-1104n may be LCS policy nodes that are configured to identify LCS policy information that describes policies for using the LCS 1002 (e.g., Central Processing Unit (CPU) burst policies (e.g., to allow CPU operation above a threshold for some time period after which a limit will be enforced), networking burst policies (e.g., to allow link utilization above a threshold for some time period after which a limit will be enforced), limited radix policies (e.g., capping the number of Transmission Control Protocol (TCP) connections allowed at the same time), data scrubbing policies (e.g., defining a maximum time period that persistent data will remain stored before it is expunged), access policies (e.g., defining access to IP address as only being allowed via a proxy address outside of a subset), hardware policies (e.g., allowing an Advanced Vector eXtension (AVX) instruction vector multiply to use a hardware offload rather than software interpolation), administrator policies (e.g., to only allow access to resource system objects or telemetry data to users having a system/infrastructure administrator role, or only allow create/delete operations on resource state tag objects for owners of a corresponding resource), and/or any other LCS policies that would be apparent one of skill in the art in possession of the present disclosure).

As such, the LCS information nodes 1104a-1104n may be configured to identify static LCS information (e.g., the LCS capabilities information discussed above) or dynamic LCS information (e.g., the LCS operating information discussed above that may be retrieved from sensor(s) coupled to the processing device 802a, networking device 804a, and storage device 806n that are being used to provide the LCS 1002 and that may be updated in real-time in the LCS information node(s) 1104a-1104n), and may be user specific and/or updatable (e.g., the LCS policy information discussed above may be specific to particular users and/or may be updated for users as policies for those users change). As such, the updating of the LCS monitoring graph model 901 may include retrieving any information about the LCS 1002 identified by the LCS node 1102 and populating that information in the LCS information node(s) 1104a-1104n connected to the LCS node 1102, linking the LCS information node(s) 1104a-1104n connected to the LCS node 1102 to sensor(s) that report information about the resource devices that are being used to provide the LCS 1002 identified by that LCS node 1102, and/or any other operations that one of skill in the art in possession of the present disclosure would recognize as enabling the functionality using the LCS monitoring graph models described below. However, while specific examples of LCS information identified by LCS information nodes has been described, one of skill in the art in possession of the present disclosure will appreciate how the LCS information nodes of the present disclosure may identify any information about an LCS while remaining within the scope of the present disclosure.

As will be appreciated by one of skill in the art in possession of the present disclosure, the resource devices used to provide the LCS 1002 may change through the provisioning of the LCS 1002, and the resource management system 304 may be configured to modify the LCS monitoring graph model 901 to remove resource device graph model nodes for resource devices that are unavailable for providing the LCS 1002, add “new” resource device graph model nodes for “new” resource devices that are then used to provide the LCS 1002, connect those “new” resource device graph model nodes to the LCS node 1102, and provide the resource information graph model nodes for the “new” resource device graph model nodes similarly as described above. As such, the LCS monitoring graph model 901 may dynamically change to reflect the current provisioning of the LCS 1002.

The method 700 then proceeds to block 712 where the resource management system performs one or more LCS monitoring operations for the LCS using the LCS monitoring graph model. As discussed in further detail below, in an embodiment of block 712 and after updating the LCS monitoring graph model 901 at block 710 for the LCS 1002 composed at block 708, the resource management system 304 may perform any of a variety of LCS monitoring operations for the LCS 1002 using the LCS monitoring graph model 901. The specific example provided herein for the method 700 describes an embodiment in which the resource management system 304 composes and monitors a plurality of LCSs, and thus the composing of each of those LCSs is described below before the discussion of the use of the LCS monitoring graph model 901 in the monitoring of those LCSs at block 712. However, while a discussion of the monitoring of a plurality of LCSs by the resource management system 304 is described below, one of skill in the art in possession of the present disclosure will appreciate how a single LCS may be monitored by the resource management system 304 similarly as described below while remaining within the scope of the present disclosure as well.

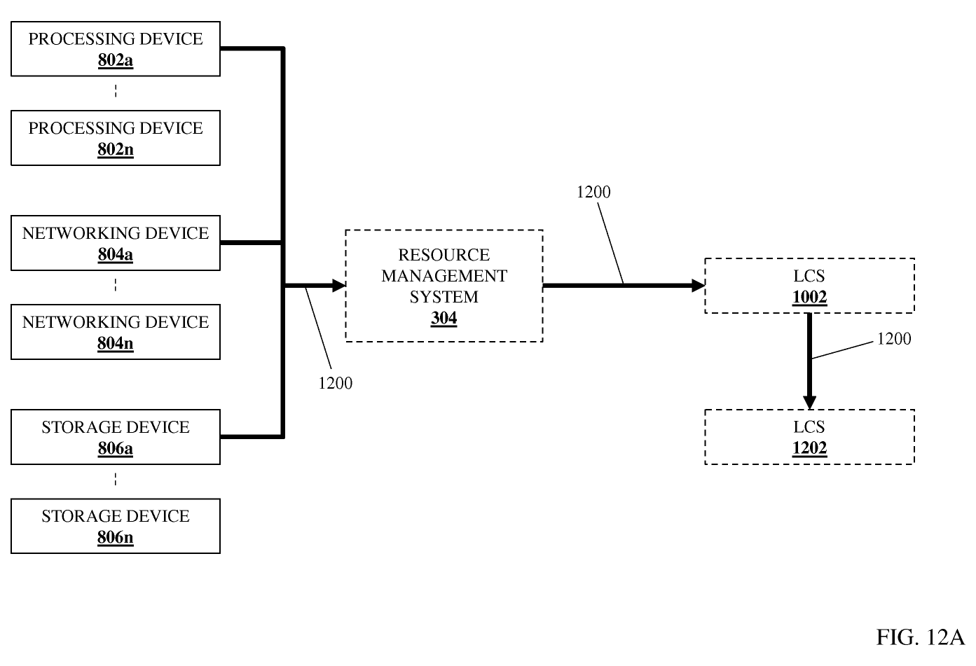

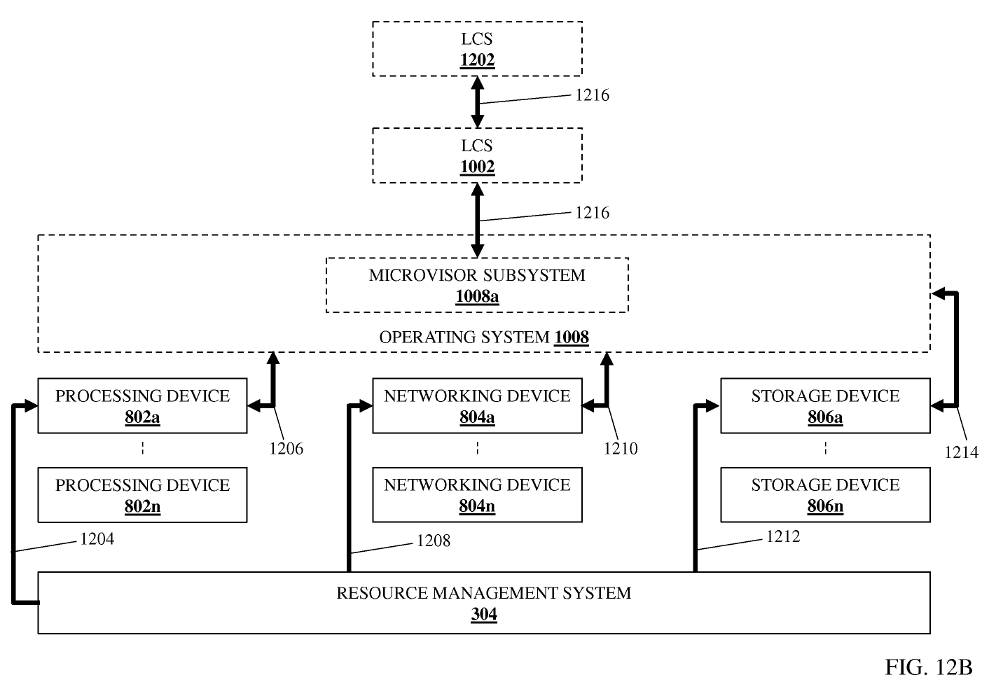

As such, following the composing of the LCS 1002 at block 708 and the updating of the LCS monitoring graph model 901 at block 710, the LCS 1002 may be monitored using the LCS monitoring graph model 901 and the method may return to decision block 706 to determine whether another instruction is received to provide another LCS similarly as described above. With reference to FIG. 12A and in response to receiving an instruction to provide an LCS during a subsequent iteration of decision block 706, the resource management system 304 may perform LCS composition operations 1200 that include composing an LCS 1202 using the processing device 802a, the networking device 804a, and the storage device 806a. As will be appreciated by one of skill in the art in possession of the present disclosure, the embodiment illustrated in FIG. 12A provides an example of the composition of a “nested” LCS 1202 using the same processing device 802a as the LCS 1002 (e.g., a first subset of core(s) in the processing device 802a may be used to provide the LCS 1002, and a second subset of core(s) in the processing device 802a may be used to provide the LCS 1202). However, while a specific example of a “nested” LCS is illustrated and described, one of skill in the art in possession of the present disclosure will appreciate how “nested” LCSs may be provided using a variety of techniques and/or in a variety of manners that will fall within the scope of the present disclosure as well.

For example, as illustrated in FIG. 12B, the LCS composition operations 1200 performed by the resource management system 304 may include processing device configuration operations 1204 that configure the processing device 802a to perform processing operations 1206 to provide the LCS 1202 (e.g., in cooperation with the operating system 1008 including the microvisor subsystem 1008a that is provided using any of the processing devices 802a-802n (and corresponding memory devices, not illustrated) available to the resource management system 304 in, for example, one of the BMSs discussed above), networking device configuration operations 1208 that configure the networking device 804a to perform networking operations 1210 to provide networking for the LCS 1202 (e.g., by transmitting data to and from the LCS 1202), and storage device configuration operations 1012 that configure the storage device 806a to perform storage operations 1214 to provide storage for the LCS 1202 (e.g., by storing data utilized by the LCS 1202). The microvisor subsystem 1008a in the operating system 1008 may then operate using the processing device 802a, the networking device 804a, and the storage device 806a to perform LCS provisioning operations 1216 to provide the LCS 1202. However, while the composition of an LCS using the simplified example of resource devices provided by the processing devices 802a-802n, networking devices 804a-804n, and storage devices 806a-806n is provided herein, one of skill in the art in possession of the present disclosure will appreciate how LCSs may be composed using a variety of resource devices while remaining within the scope of the present disclosure as well.

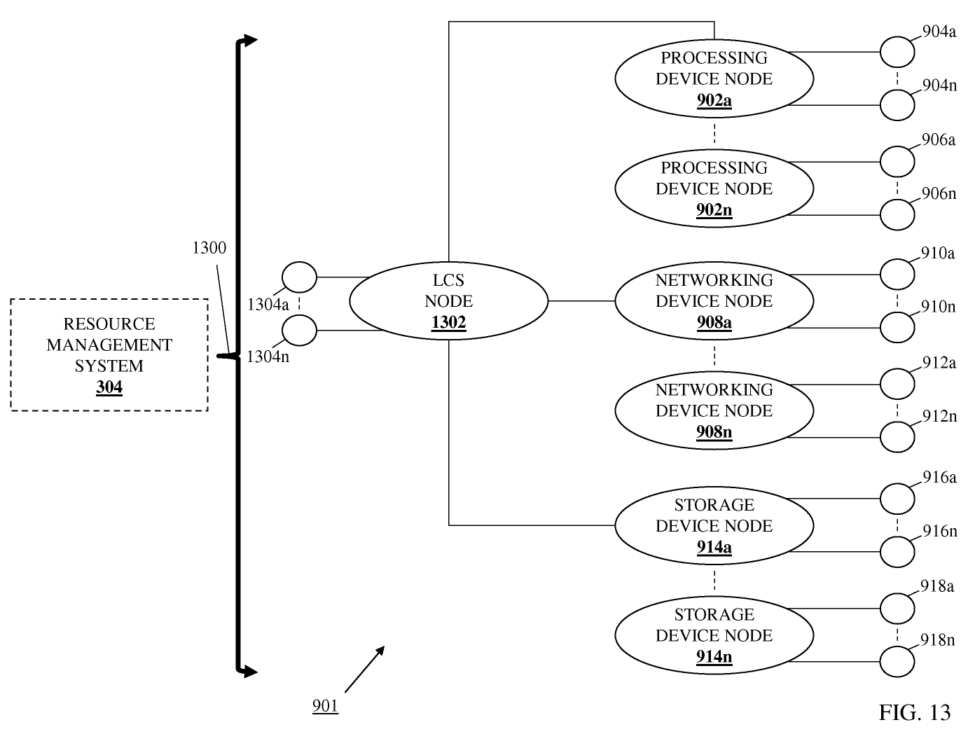

The method 700 then proceeds to a subsequent iteration of block 710 where the resource management system updates the LCS monitoring graph model. For example, with reference to FIG. 13, a specific example of LCS monitoring graph model update operations 1300 by the resource management system 304 are illustrated that provide for the updating of the LCS monitoring graph model 901 to include an LCS node 1302 for the LCS 1202 that was composed at the subsequent iteration of block 708. Furthermore, the LCS monitoring graph model 901 is also updated to provide an edge that connects the LCS node 1302 to the processing device node 902a that identifies the processing device 802a that was used to compose the LCS 1202, an edge that connects the LCS node 1302 to the networking device node 908a that identifies the networking device 804a that was used to compose the LCS 1202, and an edge that connects the LCS node 1302 to the storage device node 914a that identifies the storage device 806a that was used to compose the LCS 1202. Further still, the LCS monitoring graph model 901 is also updated to include a plurality of LCS information nodes 1304a-1304n that are each connected to the LCS node 1302 by a respective edge. As described in further detail below, the LCS information nodes 1304a-1304n may each be configured to identify information about the LCS 1202 identified by the LCS node 1302.

For example, any of the LCS information nodes 1304a-1304n may be LCS capability nodes that are configured to identify LCS capability information that describes capabilities of the LCS 1202 (e.g., system capabilities such as database provisioning capabilities, vector database provisioning capabilities, static web server provisioning capabilities, object storage provisioning capabilities, file hierarchical storage provisioning capabilities, and data movement (e.g., Direct Memory Access (DMA) provisioning capabilities; Artificial Intelligence (AI) capabilities such as Retrieval-Augmented Generation (RAG) Model (“XYZ”) provisioning capabilities, and Large Language Model (LLM) implementation provisioning capabilities; security capabilities such as OpenID Connect (OIDC) Authentication Connector provisioning capabilities, OpenTelemetry (OTEL) Trace Collector provisioning capabilities, Certificate Authority (CA) Verification provisioning capabilities, and Data Inspection Proxy provisioning capabilities; Quality of Service (QoS) provisioning capabilities that provide performance, scalability, availability, and serviceability needs for LCSs, and/or any other LCS capabilities that would be apparent one of skill in the art in possession of the present disclosure).

In another example, any of the LCS information nodes 1304a-1304n may be LCS operation nodes that are configured to identify LCS operating information that is configured to describe the current operation of the LCS 1202 (e.g., currently present and/or enabled capabilities for the LCS 1202, capability dependencies (e.g., name and version) required for the LCS 1202, configuration metadata for the LCS 1202, an Internet Protocol (IP) address for the LCS 1202, a name of the LCS 1202, a cryptographic or otherwise unique identification for the LCS 1202, credentials and account information for the LCS 1202, tenant owner information for the LCS 1202, LCS runtime policy information for the LCS 1202, and/or any other LCS operating information that would be apparent one of skill in the art in possession of the present disclosure).

In yet another example, any of the LCS information nodes 1304a-1304n may be LCS policy nodes that are configured to identify LCS policy information that describes policies for using the LCS 1202 (e.g., CPU burst policies (e.g., to allow CPU operation above a threshold for some time period after which a limit will be enforced), networking burst policies (e.g., to allow link utilization above a threshold for some time period after which a limit will be enforced), limited radix policies (e.g., capping the number of TCP connections allowed at the same time), data scrubbing policies (e.g., defining a maximum time period that persistent data will remain stored before it is expunged), access policies (e.g., defining access to IP address as only being allowed via a proxy address outside of a subset), hardware policies (e.g., allowing an AVX instruction vector multiply to use a hardware offload rather than software interpolation), administrator policies (e.g., to only allow access to resource system objects or telemetry data to users having a system/infrastructure administrator role, or only allow create/delete operations on resource state tag objects for owners of a corresponding resource), and/or any other LCS policies that would be apparent one of skill in the art in possession of the present disclosure).

As such, the LCS information nodes 1304a-1304n may be configured to identify static LCS information (e.g., the LCS capabilities information discussed above) or dynamic LCS information (e.g., the LCS operating information discussed above that may be retrieved from sensor(s) that are coupled to the processing device 802a, networking device 804a, and storage device 806a that are used to provide the LCS 1202 and that may be updated in real-time in the LCS information node(s) 1304a-1304n), and may be user specific and/or updatable (e.g., the LCS policy information discussed above may be specific to particular users and/or may be updated for users as policies for those users change). As such, the updating of the LCS monitoring graph model 901 may include retrieving any information about the LCS 1202 identified by the LCS node 1302 and populating that information in the LCS information node(s) 1304a-1304n connected to the LCS node 1302, linking the LCS information node(s) 1304a-1304n connected to the LCS node 1302 to sensor(s) that report information about the resource devices that are used to provide the LCS 1202 identified by that LCS node 1302, and/or any other operations that one of skill in the art in possession of the present disclosure would recognize as enabling the functionality using the LCS monitoring graph models described below. However, while specific examples of LCS information identified by LCS information nodes has been described, one of skill in the art in possession of the present disclosure will appreciate how the LCS information nodes of the present disclosure may identify any information about an LCS while remaining within the scope of the present disclosure.

As will be appreciated by one of skill in the art in possession of the present disclosure, the resource devices used to provide the LCS 1202 may change through the provisioning of the LCS 1202, and the resource management system 304 may be configured to modify the LCS monitoring graph model 901 to remove resource device graph model nodes for resource devices that are unavailable for providing the LCS 1202, add “new” resource device graph model nodes for “new” resource devices that are used to provide the LCS 1202 and connect those “new” resource device graph model nodes to the LCS node 1302, and provide resource information graph model nodes for the “new” resource device graph model nodes similarly as described above. As such, the LCS monitoring graph model 901 may dynamically change to reflect the current provisioning of the LCS 1202.

The method 700 then proceeds to a subsequent iteration of block 712 where the resource management system performs one or more LCS monitoring operations for the LCS using the LCS monitoring graph model. As discussed in further detail below, in an embodiment of the subsequent iteration of block 712 and after updating the LCS monitoring graph model 901 at the subsequent iteration of block 710 for the LCS 1202 composed at the subsequent iteration of block 708, the resource management system 304 may perform any of a variety of LCS monitoring operations for the LCS 1202 using the LCS monitoring graph model 901. The specific example provided herein for the method 700 describes an embodiment in which the resource management system 304 composes and monitors a plurality of LCSs, and thus the composing of those LCSs is described herein before the discussion of the use of the LCS monitoring graph model 901 in the monitoring of those LCSs at block 712. However, while a discussion of the monitoring of a plurality of LCS by the resource management system 304 is described below, one of skill in the art in possession of the present disclosure will appreciate how a single LCS may be monitored by the resource management system 304 similarly as described below while remaining within the scope of the present disclosure as well.

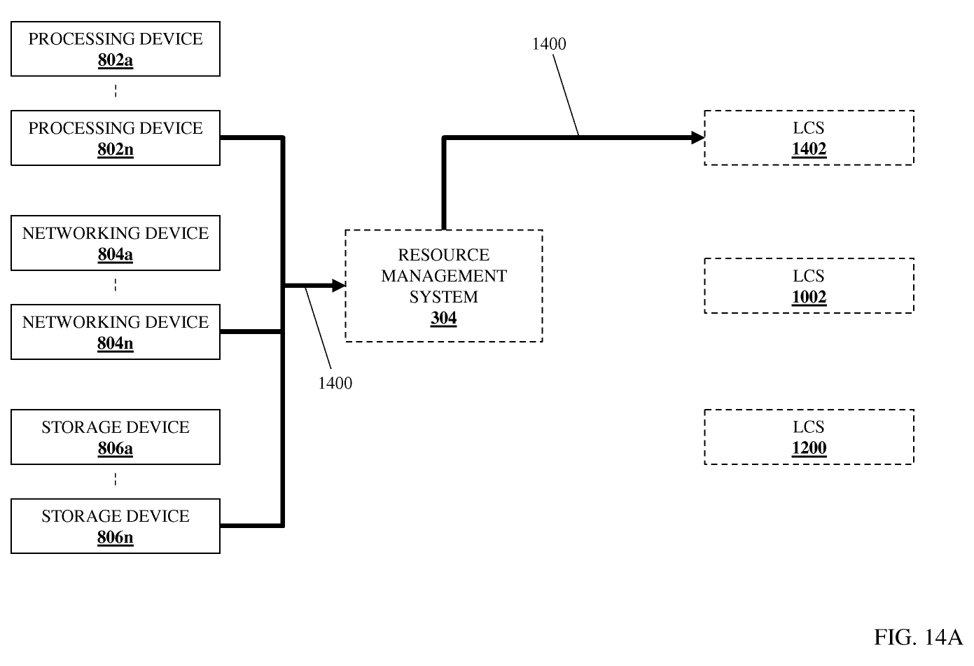

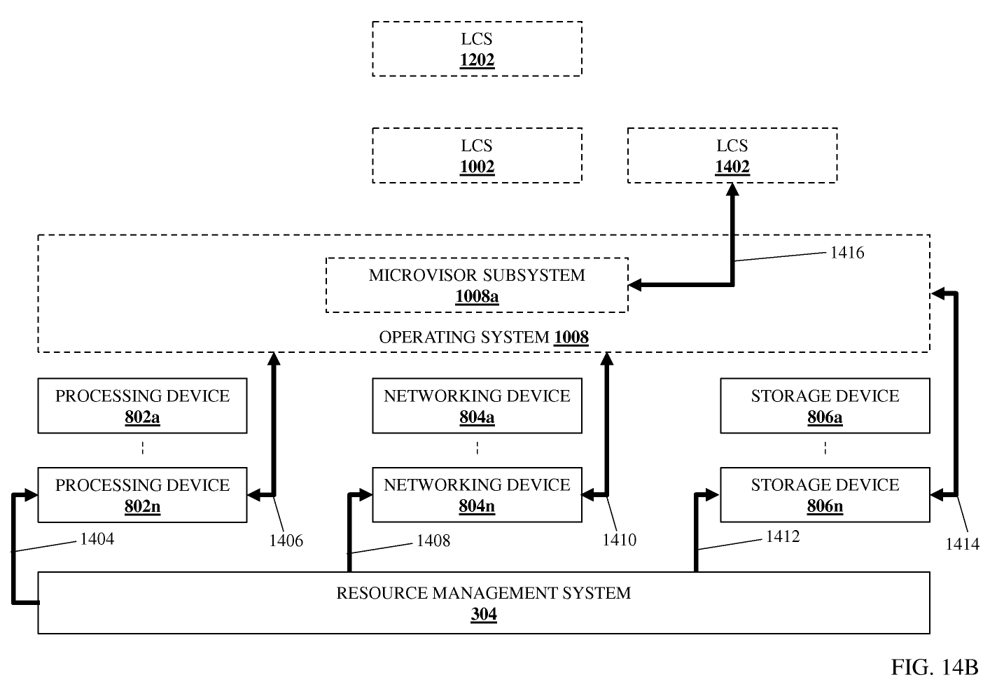

As such, following the composing of the LCS 1202 at the subsequent iteration of block 708 and the updating of the LCS monitoring graph model 901 at the subsequent iteration of block 710, the LCS 1202 may be monitored using the LCS monitoring graph model 901 and the method may return to decision block 706 to determine whether another instruction is received to provide another LCS similarly as described above. With reference to FIG. 14A and in response to receiving an instruction to provide an LCS during yet another subsequent iteration of decision block 706, the resource management system 304 may perform LCS composition operations 1400 that include composing an LCS 1402 using the processing device 802n, the networking device 804n, and the storage device 806n.

For example, as illustrated in FIG. 14B, the LCS composition operations 1400 performed by the resource management system 304 may include processing device configuration operations 1404 that configure the processing device 802n to perform processing operations 1406 to provide the LCS 1402 (e.g., in cooperation with the operating system 1008 including the microvisor subsystem 1008a that is provided using any of the processing devices 802a-802n (and corresponding memory devices, not illustrated) available to the resource management system 304 in, for example, one of the BMSs discussed above), networking device configuration operations 1408 that configure the networking device 804n to perform networking operations 1410 to provide networking for the LCS 1202 (e.g., by transmitting data to and from the LCS 1402), and storage device configuration operations 1412 that configure the storage device 806n to perform storage operations 1414 to provide storage for the LCS 1402 (e.g., by storing data utilized by the LCS 1402). The microvisor subsystem 1008a in the operating system 1008 may then operate using the processing device 802n, the networking device 804n, and the storage device 806n to perform LCS provisioning operations 1416 to provide the LCS 1402. However, while the composition of an LCS using the simplified example of resource devices provided by the processing devices 802a-802n, networking devices 804a-804n, and storage devices 806a-806n is provided herein, one of skill in the art in possession of the present disclosure will appreciate how LCSs may be composed using a variety of resource devices while remaining within the scope of the present disclosure as well.

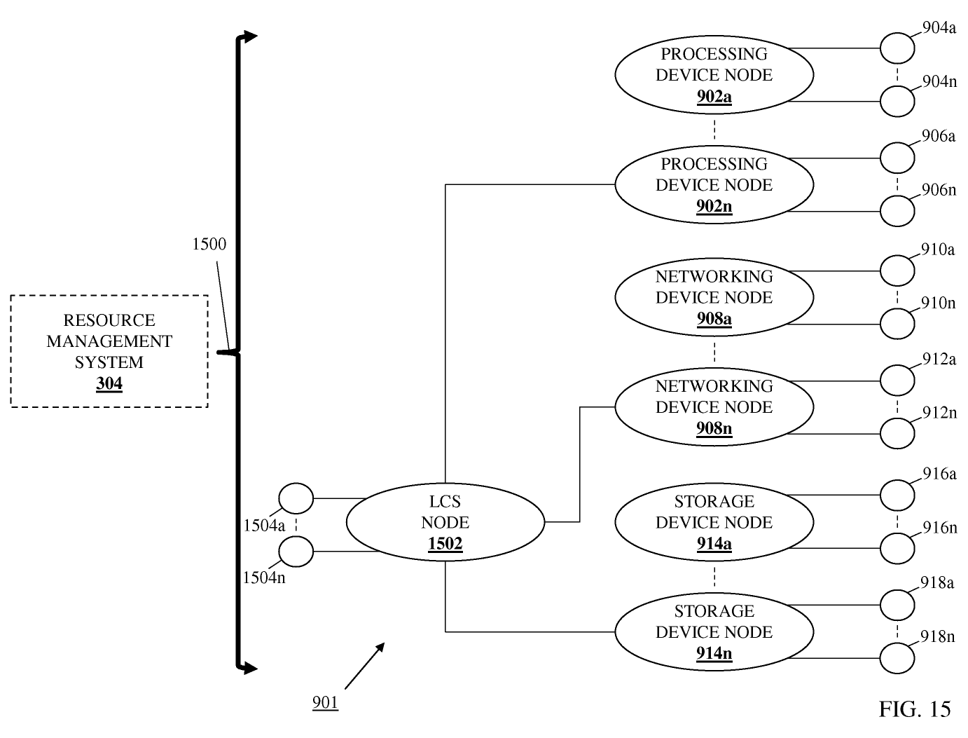

The method 700 then proceeds to yet another subsequent iteration of block 710 where the resource management system updates the LCS monitoring graph model. For example, with reference to FIG. 15, a specific example of LCS monitoring graph model update operations 1500 by the resource management system 304 are illustrated that provide for the updating of the LCS monitoring graph model 901 to include an LCS node 1502 for the LCS 1402 that was composed at the subsequent iteration of block 708. Furthermore, the LCS monitoring graph model 901 is also updated to provide an edge that connects the LCS node 1502 to the processing device node 902n that identifies the processing device 802n that was used to compose the LCS 1402, an edge that connects the LCS node 1502 to the networking device node 908n that identifies the networking device 804n that was used to compose the LCS 1402, and an edge that connects the LCS node 1502 to the storage device node 914n that identifies the storage device 806n that was used to compose the LCS 1402. Further still, the LCS monitoring graph model 901 is also updated to include a plurality of LCS information nodes 1504a-1504n that are each connected to the LCS node 1502 by a respective edge. As described in further detail below, the LCS information nodes 1504a-1504n may each be configured to identify information about the LCS 1402 identified by the LCS node 1502.

For example, any of the LCS information nodes 1504a-1504n may be LCS capability nodes that are configured to identify LCS capability information that describes capabilities of the LCS 1402 (e.g., system capabilities such as database provisioning capabilities, vector database provisioning capabilities, static web server provisioning capabilities, object storage provisioning capabilities, file hierarchical storage provisioning capabilities, and data movement (e.g., Direct Memory Access (DMA) provisioning capabilities; Artificial Intelligence (AI) capabilities such as Retrieval-Augmented Generation (RAG) Model (“XYZ”) provisioning capabilities, and Large Language Model (LLM) implementation provisioning capabilities; security capabilities such as OpenID Connect (OIDC) Authentication Connector provisioning capabilities, OpenTelemetry (OTEL) Trace Collector provisioning capabilities, Certificate Authority (CA) Verification provisioning capabilities, and Data Inspection Proxy provisioning capabilities; Quality of Service (QoS) provisioning capabilities that provide performance, scalability, availability, and serviceability needs for LCSs, and/or any other LCS capabilities that would be apparent one of skill in the art in possession of the present disclosure).

In another example, any of the LCS information nodes 1504a-1504n may be LCS operation nodes that are configured to identify LCS operating information that is configured to describe the current operation of the LCS 1402 (e.g., currently present and/or enabled capabilities for the LCS 1402, capability dependencies (e.g., name and version) required for the LCS 1402, configuration metadata for the LCS 1402, an Internet Protocol (IP) address for the LCS 1402, a name of the LCS 1402, a cryptographic or otherwise unique identification for the LCS 1402, credentials and account information for the LCS 1402, tenant owner information for the LCS 1402, LCS runtime policy information for the LCS 1402, and/or any other LCS operating information that would be apparent one of skill in the art in possession of the present disclosure).

In yet another example, any of the LCS information nodes 1504a-1504n may be LCS policy nodes that are configured to identify LCS policy information that describes policies for using the LCS 1402 (e.g., CPU burst policies (e.g., to allow CPU operation above a threshold for some time period after which a limit will be enforced), networking burst policies (e.g., to allow link utilization above a threshold for some time period after which a limit will be enforced), limited radix policies (e.g., capping the number of TCP connections allowed at the same time), data scrubbing policies (e.g., defining a maximum time period that persistent data will remain stored before it is expunged), access policies (e.g., defining access to IP address as only being allowed via a proxy address outside of a subset), hardware policies (e.g., allowing an AVX instruction vector multiply to use a hardware offload rather than software interpolation), administrator policies (e.g., to only allow access to resource system objects or telemetry data to users having a system/infrastructure administrator role, or only allow create/delete operations on resource state tag objects for owners of a corresponding resource), and/or any other LCS policies that would be apparent one of skill in the art in possession of the present disclosure).

As such, the LCS information nodes 1504a-1504n may be configured to identify static LCS information (e.g., the LCS capabilities information discussed above) or dynamic LCS information (e.g., the LCS operating information discussed above that may be retrieved from sensor(s) that are coupled to the processing device 802n, networking device 804n, and storage device 806n that are used to provide the LCS 1402 and that may be updated in real-time in the LCS information node(s) 1504a-1504n), and may be user specific and/or updatable (e.g., the LCS policy information discussed above may be specific to particular users and/or may be updated for users as policies for those users change). As such, the updating of the LCS monitoring graph model 901 may include retrieving any information about the LCS 1402 identified by the LCS node 1502 and populating that information in the LCS information node(s) 1504a-1504n connected to the LCS node 1502, linking the LCS information node(s) 1504a-1504n connected to the LCS node 1502 to sensor(s) that report information about the resource devices that are used to provide the LCS 1402 identified by that LCS node 1502, and/or any other operations that one of skill in the art in possession of the present disclosure would recognize as enabling the functionality using the LCS monitoring graph models described below. However, while specific examples of LCS information identified by LCS information nodes has been described, one of skill in the art in possession of the present disclosure will appreciate how the LCS information nodes of the present disclosure may identify any information about an LCS while remaining within the scope of the present disclosure.

As will be appreciated by one of skill in the art in possession of the present disclosure, the resource devices used to provide the LCS 1402 may change through the provisioning of the LCS 1402, and the resource management system 304 may be configured to modify the LCS monitoring graph model 901 to remove resource device graph model nodes for resource devices that are unavailable for providing the LCS 1402, add “new” resource device graph model nodes for “new” resource devices that are used to provide the LCS 1402 and connect those “new” resource device graph model nodes that are providing the LCS 1402, and connect those “new” resource device graph model nodes to corresponding resource information graph model nodes similarly as described above. As such, the LCS monitoring graph model 901 may dynamically change to reflect the current provisioning of the LCS 1402.

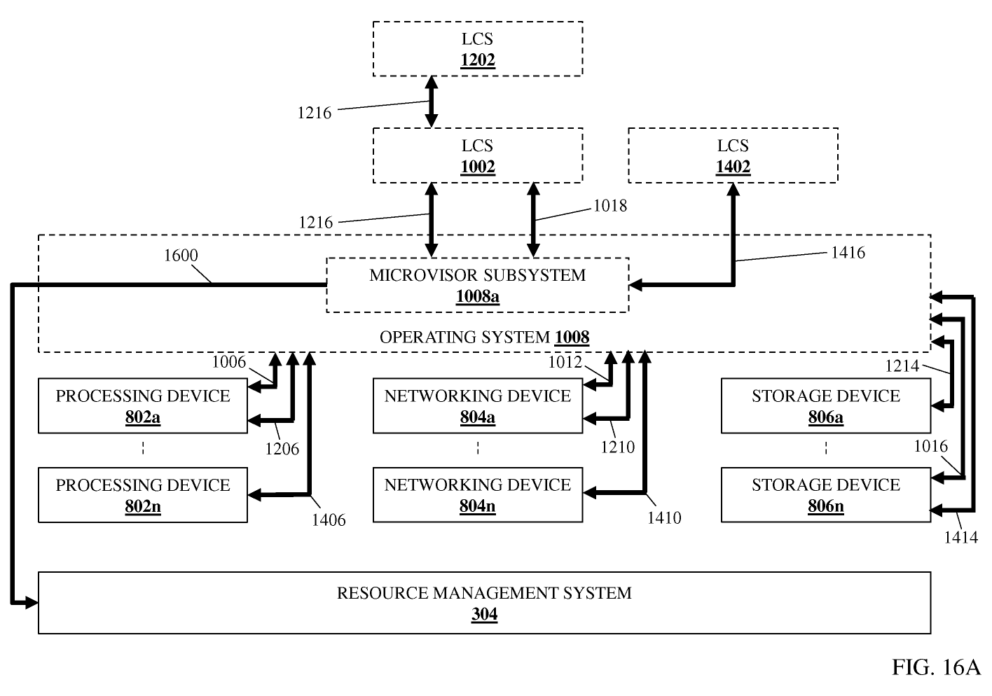

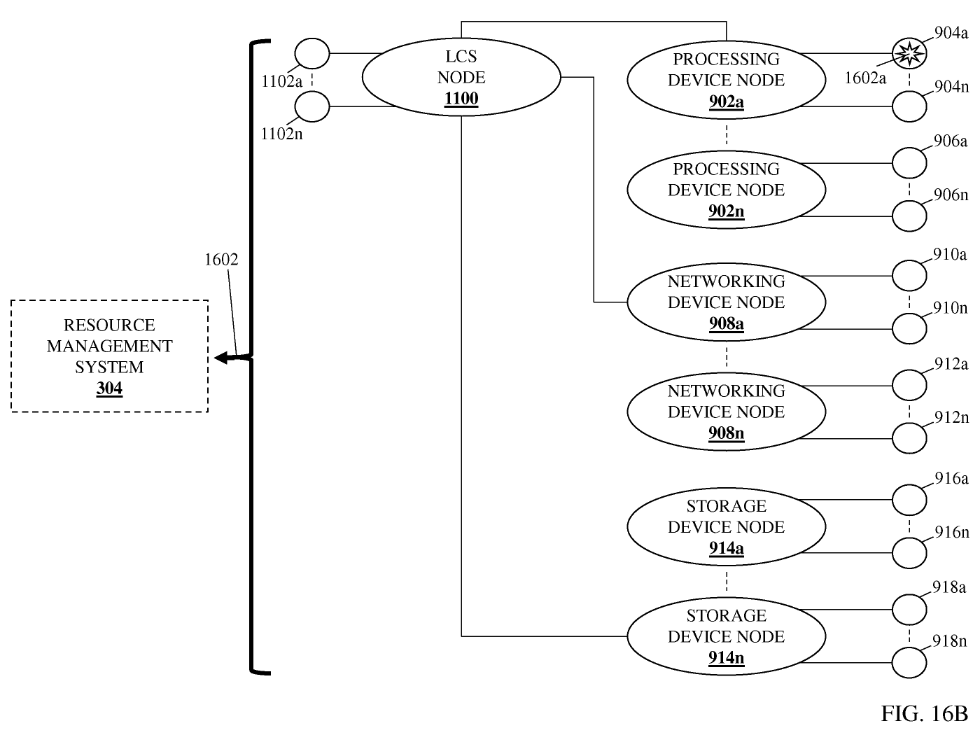

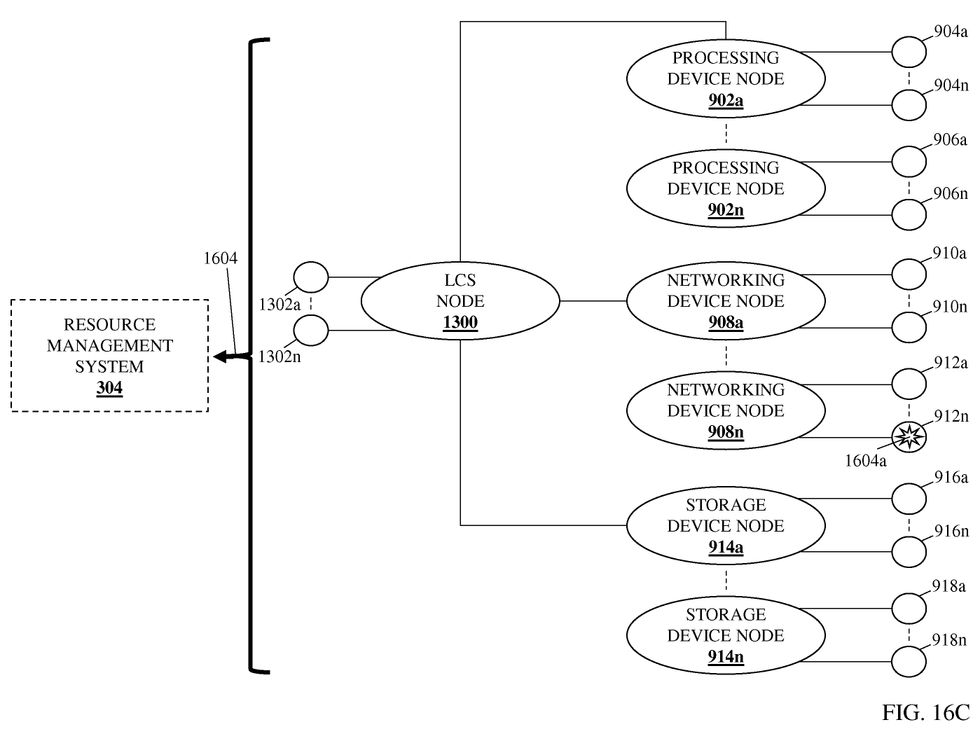

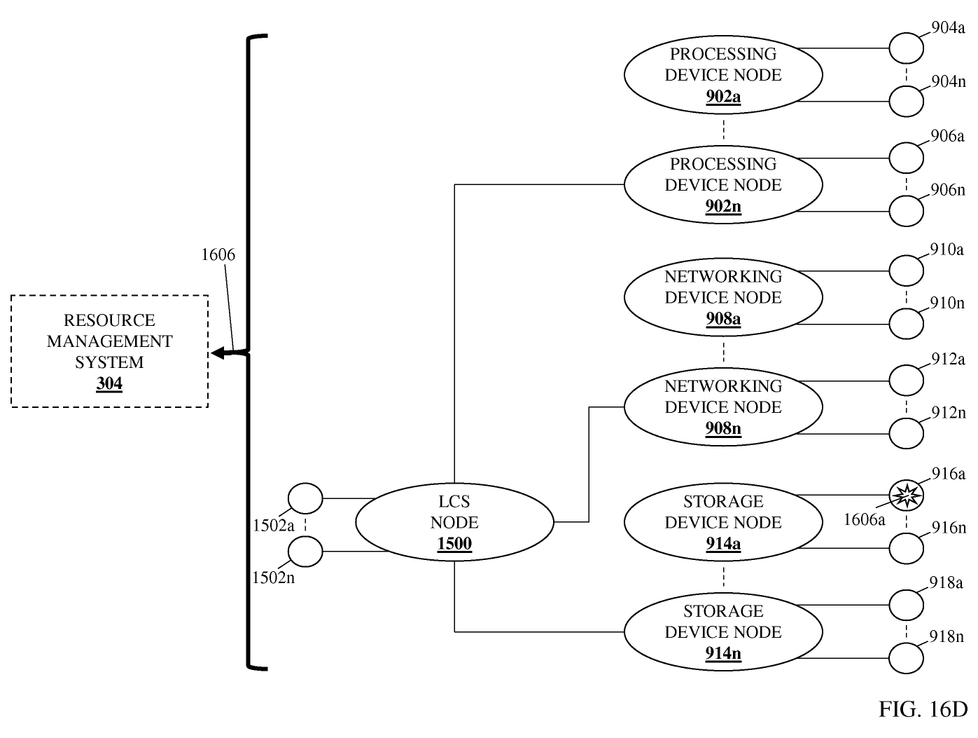

An example of the resource management system 304 using the LCS monitoring graph model 901 to monitor the LCSs 1002, 1202, and 1402 at block 712 will now be provided, but as described above, the monitoring of a single LCS using an LCS monitoring graph model generated and updated for that LCS similarly as described below will fall within the scope of the present disclosure as well. As can be seen in FIG. 16A, the microvisor subsystem 1008a in the operating system 1008 may perform the LCS provisioning operations 1018 to provide the LCS 1002, with the microvisor subsystem 1008a using the processing device 802a to perform the processing operations 1006 for the LCS 1002, the networking device 804a to perform the networking operations 1012 for the LCS 1002, and the storage device 806n to perform the storage operations 1016 for the LCS 1002.

As can also be seen in FIG. 16A, the microvisor subsystem 1008a in the operating system 1008 may perform the LCS provisioning operations 1216 to provide the LCS 1202, with the microvisor subsystem 1008a using the processing device 802a to perform the processing operations 1206 for the LCS 1202, the networking device 804a to perform the networking operations 1210 for the LCS 1202, and the storage device 806a to perform the storage operations 1214 for the LCS 1202. As can also be seen in FIG. 16A, the microvisor subsystem 1008a in the operating system 1008 may perform the LCS provisioning operations 1416 to provide the LCS 1402, with the microvisor subsystem 1008a using the processing device 802n to perform the processing operations 1406 for the LCS 1402, the networking device 804n to perform the networking operations 1410 for the LCS 1402, and the storage device 806n to perform the storage operations 1414 for the LCS 1402.

Furthermore, the microvisor subsystem 1008a in the operating system 1008 may also perform LCS operating information provisioning operations 1600 that include reporting any information generated in response to operation of the LCS provisioning operations 1018, 1216, and 1416; the processing operations 1006, 1206, and 1406; the networking operations 1012, 1210, and 1410; and the storage operations 1214, 1016, and 1414 to the resource management system 304. For example, at block 712, the microvisor subsystem 1008a may monitor any sensors provided for the processing devices 802a-802n, the networking devices 804a-804n, the storage devices 806a-806n, and the LCSs 1002, 1202, and 1402, and report any information generated by those sensors to the resource management system 304 as part of the LCS monitoring information reporting operations 1600. However, while a specific example of the provisioning of operating information generated as part of the provisioning of LCSs has been provided one of skill in the art in possession of the present disclosure will appreciate how a variety of operating information may be generated as part of the provisioning of LCSs and may be provided to the microvisor subsystem of the present disclosure while remaining within the scope of the present disclosure as well.

As will be appreciated by one of skill in the art in possession of the present disclosure, the operating information received from the microvisor subsystem 1008a by the resource management system 304 may then be provided in the LCS monitoring graph model 901 in the processing device information nodes 904a-904n and 906a-906n that are configure to identify that operating information, the networking device information nodes 910a-910n and 912a-912n that are configure to identify that operating information, the storage device information nodes 916a-916n and 918a-918n that are configured to identify that operating information, and the LCS information nodes 1102a-1102n, 1302a-1302n, and 1502a-1502n that are configured to identify that operating information. As such, one of skill in the art in possession of the present disclosure will appreciate how the CLS monitoring graph model 901 provides a “digital twin” of the LCS provisioning subsystem 300 with nodes that identify each of the resource devices included therein and the LCSs provided by those resource devices, as well as nodes that identify the capabilities, current operation, and policies of each of those resource devices and LCSs. Furthermore, operating information may be dynamically updated in real time for each of those resource devices and LCSs, allowing for the monitoring of their operation, the determination of whether their operation complies with operating policies, and/or otherwise allowing any changes to resource devices and LCSs to be instantly identified and correlated.

With reference to FIG. 16B, an example of the resource management system 304 performing LCS monitoring operations 1602 is provided in which operating information identified by the processing device information node 904a may be compared to policy information identified by the processing device information node 904n to determine that the current operation of the processing device 802a identified by the processing device node 902a violated a policy (e.g., as indicated by element 1602a). For example, the comparison of the operating information identified by the processing device information node 904a to the policy information identified by the processing device information node 904n may identify that the current operation of the processing device 802a identified by the processing device node 902a has exceeded a threshold processing device operating level (e.g., a user has exceeded an amount of processing they purchased for the LCS 1002 identified by the LCS node 1100) and, in response, the resource management system 304 may throttle the processing device 802a, activate a billing system to bill a user for exceeding the threshold processing device operating level, and/or perform other LCS monitoring operations that would be apparent to one of skill in the art in possession of the present disclosure.

With reference to FIG. 16C, an example of the resource management system 304 performing LCS monitoring operations 1604 is provided in which operating information identified by the networking device information node 912n may be compared to policy information identified by the networking device information node 912a to determine that the current operation of the networking device 804n identified by the networking device node 908n violated a policy (e.g., as indicated by element 1604a). For example, the comparison of the operating information identified by the networking device information node 912n to the policy information identified by the networking device information node 912a may identify that the current operation of the networking device 804n identified by the networking device node 908n has exceeded a threshold networking device operating level (e.g., a user has exceeded an amount of networking bandwidth they purchased for the LCS 1202 identified by the LCS node 1300) and, in response, the resource management system 304 may throttle the networking device 804n, activate a billing system to bill a user for exceeding the threshold networking device operating level, and/or perform other LCS monitoring operations that would be apparent to one of skill in the art in possession of the present disclosure.

With reference to FIG. 16D, an example of the resource management system 304 performing LCS monitoring operations 1606 is provided in which operating information identified by the storage device information node 916a may be compared to policy information identified by the storage device information node 916n to determine that the current operation of the storage device 806a identified by the storage device node 914a violated a policy (e.g., as indicated by element 1606a). For example, the comparison of the operating information identified by the storage device information node 916a to the policy information identified by the storage device information node 916n may identify that the current operation of the storage device 806a identified by the storage device node 914a has exceeded a threshold storage device operating level (e.g., a user has exceeded a storage capacity they purchased for the LCS 1402 identified by the LCS node 1500) and, in response, the resource management system 304 may throttle the storage device 806a, activate a billing system to bill a user for exceeding the threshold storage device operating level, and/or perform other LCS monitoring operations that would be apparent to one of skill in the art in possession of the present disclosure.

However, while several specific examples of the monitoring of the LCSs 1002, 1202, and 1402 using the LCS monitoring graph model 901 to determine when the operation of processing devices, networking devices, and/or storage devices exceed policies have been described, one of skill in the art in possession of the present disclosure will appreciate how such monitoring may determine when the operation of the LCSs 1002, 1303, and 1402 exceeds policies as well (e.g., detecting that an LCS has exceeded a link utilization threshold in a network burst policy such that the network link must be throttled until overall conditions improve, identifying violation of a threat intelligence policy by an LCS such as anomalous event(s) or traffic patterns on an application provided by the LCS or workload from non-administrator user or from an administrator user from a different geographic location, etc.) Furthermore, while the examples above focus on the use of the LCS monitoring graph model 901 to perform operation policy compliance determinations, one of skill in the art in possession of the present disclosure will appreciate how the LCS monitoring graph model of the present disclosure may be used to monitor any information about the LCSs being provided by an LCS provisioning system while remaining within the scope of the present disclosure as well.

For example, one of skill in the art in possession of the present disclosure will appreciate how the operation of the processing devices, networking devices, and/or storage devices to provide the LCSs 1002, 1202, and 1402 may be stored in a database by the resource management system 304 and used to forecast the future use of the processing devices 802a-802n, networking devices 804a-804n, and/or storage devices 806a-806n for providing LCSs. Furthermore, one of skill in the art in possession of the present disclosure will also appreciate how operation of the processing devices 802a-802n, networking devices 804a-804n, and/or storage devices 806a-806n used to provide the LCSs 1002, 1202, and 1402 may be used to identify and remediate configuration “drifts” (i.e., differences between the current operation and a desired operation) by those processing devices, networking devices, and/or storage devices.

As such, the resource information graph model nodes for a resource device graph model node associated with a resource device may be configured as sensors or triggers, and one of skill in the art in possession of the present disclosure will appreciate how the resource information graph model nodes may be used to update performance counters, capture telemetry metrics, and/or may be used to perform other monitoring operations known in the art. To provide a specific example, the resource information graph model nodes described above allow the processing and memory usage by the “nested” LCS 1202 to be tracked when the “nested” LCS 1202 begins providing a virtual machine and until that LCS is finished providing that virtual machine, and allows that processing and memory usage to be distinguished from the processing and memory usage of the LCS 1002 that is providing that “nested” LCS 1202 (i.e., using the same processing device 802a).

Furthermore, the resource information graph model nodes allow the runtime transient state of each resource device used to provide an LCS to be monitored in order to analyze the behavior of the LCS at discrete levels for use inferring causality of any event that occurs with the LCS or the resource devices that are used to provide that LCS. Further still, graph embedding techniques may be used with the LCS monitoring model graphs of the present disclosure to translate those LCS monitoring model graphs as vector representations in order to, for example, determine if processing device cores providing an LCS are reporting higher than normal processing cycle usage states that will cause performance issues or effect the stability of the LCS, with vector embedding used to detect any potential for “drift” in order to allow for measures to be performed to prevent such drift.

Thus, systems and methods have been described that provide a graph model that may be used to monitor the operation of an LCS that has been composed using a plurality of resource devices. The graph-modeling-based LCS monitoring system of the present disclosure may include a resource management system coupled to resource devices. The resource management system identifies the resource devices and generates an LCS monitoring graph model with resource device nodes identifying the resource devices, and respective resource operation nodes connected via edges to those resource device nodes and configured to identify a current operation of their identified resource devices. The resource management system then composes an LCS using a first subset of the resource devices and, in response, updates the LCS monitoring graph model to include an LCS node that identifies the LCS and that is connected to the resource device nodes identifying the first subset of the resource devices. The resource management system then uses information identified from respective resource operation node(s) connected to the resource device nodes identifying the first subset of the resource devices to perform LCS monitoring operation(s) for the LCS. As such, relatively low-level, real-time monitoring of LCSs may be performed to understand and report the operations of the resource devices providing the LCS, enable the billing of the utilization of any particular resource devices, forecast the future use of resource devices for LCSs, remediate configuration “drifts” by resource devices that provide LCSs, and/or provide other monitoring benefits that would be apparent to one of skill in the art in possession of the present disclosure.

Thus, one of skill in the art in possession of the present disclosure will appreciate how the systems and methods of the present disclosure provide for the granular tracking of LCS provisioning using physical or logical resource devices in order to monitor the transient changes in the LCS and identify diverse correlations between the distributed components used to provide the LCS. Furthermore, scalability and performance efficiency benefits may be achieved by applying a generic resource information schema across a variety of types of resource devices and leveraging inferencing capabilities of graph embeddings. As will be appreciated by one of skill in the art in possession of the present disclosure, the “digital twinning” of LCS provisioning systems and the LCSs they provide enables the discrete accounting of different feature utilization by users.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. A graph-modeling-based Logically Composed System (LCS) monitoring system, comprising:
a plurality of resource devices; and
a resource management system that is coupled to the plurality of resource devices and that is configured to:
identify the plurality of resource devices and, in response, generate a Logically Composed System (LCS) monitoring graph model that includes:
respective resource device graph model nodes identifying each of the plurality of resource devices; and
a respective resource operation graph model node connected to each of the respective resource device graph model nodes via a respective graph model edge, wherein each respective resource operation graph model node is configured to identify a current operation of the resource device identified by the respective resource device graph model node connected to that respective resource information graph model node;
compose an LCS using a first subset of the plurality of resource devices and, in response, update the LCS monitoring graph model to include:
an LCS graph model node that identifies the LCS and that is connected to the respective resource device graph model nodes identifying each of first subset of the plurality of resource devices used to compose the LCS; and
perform, using information identified from at least one of the respective resource operation graph model nodes connected to the respective resource device graph model nodes that identify each of first subset of the plurality of resource devices used to compose the LCS, at least one LCS monitoring operation for the LCS.

2. The system of claim 1, wherein the LCS monitoring graph model generated in response to identifying the plurality of resource devices includes:
a respective resource capability graph model node connected to each of the respective resource device graph model nodes via a respective graph model edge, wherein each respective resource capability graph model node is configured to identify a capability of the resource device identified by the respective resource device graph model node connected to that respective resource information graph model node, and
wherein the at least one LCS monitoring operation for the LCS is performed using information identified from at least one of the respective resource capability graph model nodes connected to the respective resource device graph model nodes that identify each of first subset of the plurality of resource devices used to compose the LCS.

3. The system of claim 1, wherein the LCS monitoring graph model generated in response to identifying the plurality of resource devices includes:
a respective resource policy graph model node connected to each of the respective resource device graph model nodes via a respective graph model edge, wherein each respective resource policy graph model node is configured to identify a policy for using the resource device identified by the respective resource device graph model node connected to that respective resource information graph model node, and
wherein the at least one LCS monitoring operation for the LCS is performed using information identified from at least one of the respective resource policy graph model nodes connected to the respective resource device graph model nodes that identify each of first subset of the plurality of resource devices used to compose the LCS.

4. The system of claim 1, wherein the LCS monitoring graph model updated in response to composing the LCS using the first subset of the plurality of resource device includes:
an LCS operation graph model node connected to the LCS graph model node via a graph model edge, wherein the LCS operation graph model node is configured to identify a current operation of the LCS identified by the LCS graph model node, and
wherein the at least one LCS monitoring operation for the LCS is performed using information identified from the LCS operation graph model node.

5. The system of claim 1, wherein the LCS monitoring graph model updated in response to composing the LCS using the first subset of the plurality of resource device includes:
an LCS capability graph model node connected to the LCS graph model node via a graph model edge, wherein the LCS capability graph model node is configured to identify a capability of the LCS identified by the LCS graph model node, and
wherein the at least one LCS monitoring operation for the LCS is performed using information identified from the LCS capability graph model node.

6. The system of claim 1, wherein the LCS monitoring graph model updated in response to composing the LCS using the first subset of the plurality of resource device includes:
an LCS policy graph model node connected to the LCS graph model node via a graph model edge, wherein the LCS policy graph model node is configured to identify a policy for using the LCS identified by the LCS graph model node, and
wherein the at least one LCS monitoring operation for the LCS is performed using information identified from the LCS policy graph model node.

7. An Information Handling System (IHS), comprising:
a processing system; and
a memory system that is coupled to the processing system and that includes instructions that, when executed by the processing system, cause the processing system to provide a resource management engine that is configured to:
identify a plurality of resource devices that are coupled to the processing system and, in response, generate a Logically Composed System (LCS) monitoring graph model that includes:
respective resource device graph model nodes identifying each of the plurality of resource devices; and
a respective resource operation graph model node connected to each of the respective resource device graph model nodes via a respective graph model edge, wherein each respective resource operation graph model node is configured to identify a current operation of the resource device identified by the respective resource device graph model node connected to that respective resource information graph model node;
compose an LCS using a first subset of the plurality of resource devices and, in response, update the LCS monitoring graph model to include:
an LCS graph model node that identifies the LCS and that is connected to the respective resource device graph model nodes identifying each of first subset of the plurality of resource devices used to compose the LCS; and
perform, using information identified from at least one of the respective resource operation graph model nodes connected to the respective resource device graph model nodes that identify each of first subset of the plurality of resource devices used to compose the LCS, at least one LCS monitoring operation for the LCS.

8. The IHS of claim 7, wherein the LCS monitoring graph model generated in response to identifying the plurality of resource devices includes:
a respective resource capability graph model node connected to each of the respective resource device graph model nodes via a respective graph model edge, wherein each respective resource capability graph model node is configured to identify a capability of the resource device identified by the respective resource device graph model node connected to that respective resource information graph model node, and
wherein the at least one LCS monitoring operation for the LCS is performed using information identified from at least one of the respective resource capability graph model nodes connected to the respective resource device graph model nodes that identify each of first subset of the plurality of resource devices used to compose the LCS.

9. The IHS of claim 7, wherein the LCS monitoring graph model generated in response to identifying the plurality of resource devices includes:
a respective resource policy graph model node connected to each of the respective resource device graph model nodes via a respective graph model edge, wherein each respective resource policy graph model node is configured to identify a policy for using the resource device identified by the respective resource device graph model node connected to that respective resource information graph model node, and
wherein the at least one LCS monitoring operation for the LCS is performed using information identified from at least one of the respective resource policy graph model nodes connected to the respective resource device graph model nodes that identify each of first subset of the plurality of resource devices used to compose the LCS.

10. The IHS of claim 9, wherein the performing the at least one LCS monitoring operation for the LCS includes:
determining that the current operation of at least one of the first subset of the plurality of resource devices used to compose the LCS conflicts with the policy for using the at least one of the first subset of the plurality of resource devices used to compose the LCS.

11. The IHS of claim 7, wherein the LCS monitoring graph model updated in response to composing the LCS using the first subset of the plurality of resource device includes:
an LCS operation graph model node connected to the LCS graph model node via a graph model edge, wherein the LCS operation graph model node is configured to identify a current operation of the LCS identified by the LCS graph model node, and
wherein the at least one LCS monitoring operation for the LCS is performed using information identified from the LCS operation graph model node.

12. The IHS of claim 7, wherein the LCS monitoring graph model updated in response to composing the LCS using the first subset of the plurality of resource device includes:
an LCS capability graph model node connected to the LCS graph model node via a graph model edge, wherein the LCS capability graph model node is configured to identify a capability of the LCS identified by the LCS graph model node, and
wherein the at least one LCS monitoring operation for the LCS is performed using information identified from the LCS capability graph model node.

13. The IHS of claim 7, wherein the LCS monitoring graph model updated in response to composing the LCS using the first subset of the plurality of resource device includes:
an LCS policy graph model node connected to the LCS graph model node via a graph model edge, wherein the LCS policy graph model node is configured to identify a policy for using the LCS identified by the LCS graph model node, and
wherein the at least one LCS monitoring operation for the LCS is performed using information identified from the LCS policy graph model node.

14. A method for monitoring an LCS using graph modeling, comprising:
identifying, by a resource management system, a plurality of resource devices and, in response, generating a Logically Composed System (LCS) monitoring graph model that includes:
respective resource device graph model nodes identifying each of the plurality of resource devices; and
a respective resource operation graph model node connected to each of the respective resource device graph model nodes via a respective graph model edge, wherein each respective resource operation graph model node is configured to identify a current operation of the resource device identified by the respective resource device graph model node connected to that respective resource information graph model node;
composing, by the resource management system, an LCS using a first subset of the plurality of resource devices and, in response, update the LCS monitoring graph model to include:
an LCS graph model node that identifies the LCS and that is connected to the respective resource device graph model nodes identifying each of first subset of the plurality of resource devices used to compose the LCS; and
performing, by the resource management system using information identified from at least one of the respective resource operation graph model nodes connected to the respective resource device graph model nodes that identify each of first subset of the plurality of resource devices used to compose the LCS, at least one LCS monitoring operation for the LCS.

15. The method of claim 14, wherein the LCS monitoring graph model generated in response to identifying the plurality of resource devices includes:
a respective resource capability graph model node connected to each of the respective resource device graph model nodes via a respective graph model edge, wherein each respective resource capability graph model node is configured to identify a capability of the resource device identified by the respective resource device graph model node connected to that respective resource information graph model node, and
wherein the at least one LCS monitoring operation for the LCS is performed using information identified from at least one of the respective resource capability graph model nodes connected to the respective resource device graph model nodes that identify each of first subset of the plurality of resource devices used to compose the LCS.

16. The method of claim 14, wherein the LCS monitoring graph model generated in response to identifying the plurality of resource devices includes:
a respective resource policy graph model node connected to each of the respective resource device graph model nodes via a respective graph model edge, wherein each respective resource policy graph model node is configured to identify a policy for using the resource device identified by the respective resource device graph model node connected to that respective resource information graph model node, and
wherein the at least one LCS monitoring operation for the LCS is performed using information identified from at least one of the respective resource policy graph model nodes connected to the respective resource device graph model nodes that identify each of first subset of the plurality of resource devices used to compose the LCS.

17. The method of claim 16, wherein the performing the at least one LCS monitoring operation for the LCS includes:
determining that the current operation of at least one of the first subset of the plurality of resource devices used to compose the LCS conflicts with the policy for using the at least one of the first subset of the plurality of resource devices used to compose the LCS.

18. The method of claim 14, wherein the LCS monitoring graph model updated in response to composing the LCS using the first subset of the plurality of resource device includes:
an LCS operation graph model node connected to the LCS graph model node via a graph model edge, wherein the LCS operation graph model node is configured to identify a current operation of the LCS identified by the LCS graph model node, and
wherein the at least one LCS monitoring operation for the LCS is performed using information identified from the LCS operation graph model node.

19. The method of claim 14, wherein the LCS monitoring graph model updated in response to composing the LCS using the first subset of the plurality of resource device includes:
an LCS capability graph model node connected to the LCS graph model node via a graph model edge, wherein the LCS capability graph model node is configured to identify a capability of the LCS identified by the LCS graph model node, and
wherein the at least one LCS monitoring operation for the LCS is performed using information identified from the LCS capability graph model node.

20. The method of claim 14, wherein the LCS monitoring graph model updated in response to composing the LCS using the first subset of the plurality of resource device includes:
an LCS policy graph model node connected to the LCS graph model node via a graph model edge, wherein the LCS policy graph model node is configured to identify a policy for using the LCS identified by the LCS graph model node, and
wherein the at least one LCS monitoring operation for the LCS is performed using information identified from the LCS policy graph model node.
